(19) United States
(12) Patent Application Publication
(10) Pub. No.: US 2026/0353548 A1
(43) Pub. Date: Nov. 5, 2026

(54) ELECTRONIC DEVICE INCLUDING FLEXIBLE PRINTED CIRCUIT BOARD

(71) Applicant: Samsung Electronics Co., Ltd., Suwon-si (KR)

(72) Inventors: Jedok KIM, Suwon-si (KR); Jaeseok PARK, Suwon-si (KR); Bumjin PARK, Suwon-si (KR)

(21) Appl. No.: 19/450,940

(22) Filed: Jan. 16, 2026

Related U.S. Application Data
(63) Continuation of application No. PCT/KR2025/021732, filed on Dec. 15, 2025.

(30) Foreign Application Priority Data
Apr. 30, 2025 (KR) 10-2025-0057401
Jun. 11, 2025 (KR) 10-2025-0076331

(51) Int. Cl. H05K 1/02; G04C 10/00; G04G 17/04; H02J 50/00; H02J 50/10; H05K 1/14; H05K 1/16

(52) U.S. Cl. CPC H05K 1/0218; G04C 10/00; G04G 17/04; H02J 50/005; H02J 50/10; H05K 1/147; H05K 1/16

(57) ABSTRACT

An electronic device may include: a housing; a first PCB including a first electronic component; a wireless charging coil configured to receive power; a second PCB including a second electronic component at least partially surrounded by the wireless charging coil; and a flexible printed circuit board electrically connecting the first PCB and the second PCB. The flexible printed circuit board may include: a first connector connected to the first PCB; a second connector connected to the second PCB and the wireless charging coil; plurality of conductive lines disposed between the first connector and the second connector; and a first ground portion including two ground layers spaced apart from each other. Two of the plurality of conductive lines supply AC power received through the wireless charging coil to the first PCB, and the two ground layers of the first ground portion to overlap the AC power transmission lines.

### CROSS-REFERENCE TO RELATED APPLICATIONS

This application is a continuation of International Application No. PCT/KR2025/021732 designating the United States, filed on Dec. 15, 2025, in the Korean Intellectual Property Receiving Office and claiming priority to Korean Patent Application Nos. 10-2025-0057401, filed on Apr. 30, 2025, and 10-2025-0076331, filed on Jun. 11, 2025, in the Korean Intellectual Property Office, the disclosures of each of which are incorporated by reference herein in their entireties.

### BACKGROUND

### Field

Embodiments of the disclosure relate to an electronic device and, for example, to an electronic device including a flexible printed circuit board.

### Description of Related Art

In line with remarkable development of information and communication technology, semiconductor technology, and the like, the dissemination and use of various electronic devices are rapidly increasing. Recent electronic devices are being developed to be carried and used for communication.

Electronic devices may refer to devices that perform specific functions according to loaded programs, such as from home appliances, electronic organizers, portable multimedia players, mobile communication terminals, tablet PCs, video/audio devices, desktop/laptop computers, or vehicle navigation systems. For example, such electronic devices may output stored information as sounds or images. As the degree of integration of electronic devices increases and ultra-high-speed, large-capacity wireless communication becomes widespread, various functions may recently be incorporated into a single electronic device such as a mobile communication terminal. For example, not only communication functions but also entertainment functions such as gaming, multimedia functions such as music/video playback, communication and security functions such as mobile banking, or schedule management or electronic wallet functions are being integrated into a single electronic device. Such electronic devices are being miniaturized to be conveniently carried by users.

The above-described information may be provided as a related art for the purpose of aiding understanding of the disclosure. No assertion or determination is made regarding whether any of the above-described content can be applied as a prior art in relation to the disclosure.

### SUMMARY

The disclosure relates to an electronic device. According to an example embodiment, an electronic device may include: a housing including a plate; a first printed circuit board (PCB) including a first electronic component and a first ground plane; a wireless charging coil disposed adjacent to the plate and configured to receive power with respect to a wireless power transmission device; a second PCB including a second electronic component and a second ground plane, whereint the second electronic component at least partially surrounded by the wireless charging coil when viewed in a direction perpendicular to the plate; and a flexible printed circuit board electrically connecting the first PCB and the second PCB, wherein the flexible printed circuit board may include: a first connector configured to be connected to the first PCB; a second connector configured to be connected to the second PCB and the wireless charging coil; a plurality of conductive lines disposed between the first connector and the second connector; and a first ground portion which includes two ground layers that are spaced apart from each other and which is electrically connected to at least one of the first ground plane and the second ground plane. The second connector is electrically connected to the wireless charging coil and the plurality of conductive lines. Two of the plurality of conductive lines may be used as alternating current (AC) power transmission lines configured to supply AC power received through the wireless charging coil to the first PCB, and the two ground layers of the first ground portion may be disposed to overlap the AC power transmission lines when viewed in a direction perpendicular to the plate.

The disclosure relates to a wearable electronic device. According to an example embodiment, an electronic device may include: a housing including a plate configured to form an external appearance of the electronic device in a first direction; a first PCB disposed within the housing and a first electronic component connected to the first PCB; a second PCB disposed within the housing, disposed on a substantially same plane with a wireless charging coil, and at least partially surrounded by the wireless charging coil, and a second electronic component disposed on the second PCB and formed spaced apart from the first PCB in the first direction; the wireless charging coil disposed adjacent to the plate in a second direction opposite to the first direction and configured to transmit and/or receive power from an external electronic device or a wireless power transmission device; a flexible printed circuit board configured to transmit and/or receive power and/or signals between the first electronic component and the second electronic component by connecting the first PCB and the second PCB, and disposed to at least partially overlap with the wireless charging coil; and a ground portion disposed adjacent to the second electronic component and the flexible printed circuit board, wherein the ground portion includes two ground layers spaced apart in the second direction and electrically separated from each other.

The disclosure relates to an electronic device. According to an example embodiment, an electronic device may include: a housing including a plate configured to form an external appearance of the electronic device in a first direction; a first PCB disposed within the housing; a wireless charging coil disposed adjacent to the plate in a second direction opposite to the first direction and configured to transmit and/or receive power with respect to an external electronic device or a wireless power transmission device; another printed circuit board disposed within the housing and disposed on a substantially same plane with the wireless charging coil to at least partially surround the wireless charging coil or disposed such that at least a portion thereof overlaps at least a portion of the wireless charging coil when viewed in the second direction; a ground portion disposed on a first side of the printed circuit board facing the first direction and/or a second side facing the second direction, wherein the ground portion includes two ground layers that are electrically separated and continuously disposed.

### BRIEF DESCRIPTION OF THE DRAWINGS

The above and other aspects, features and/or advantages of certain embodiments of the present disclosure will be more apparent from the following detailed description, taken in conjunction with the accompanying drawings, in which:

FIG. 1 is a block diagram illustrating an example electronic device inside a network environment according to various embodiments.

FIG. 2 is a front perspective view illustrating an example electronic device according to various embodiments.

FIG. 3 is a rear perspective view illustrating the electronic device of FIG. 2 according to various embodiments.

FIG. 4 is a perspective view of various components included in an electronic device according to various embodiments.

FIGS. 5A and 5B are perspective views illustrating a portion of an antenna module and a flexible printed circuit board according to various embodiments.

FIGS. 6A, 6B, 6C and 6D are diagrams illustrating a portion of a second PCB according to various embodiments.

FIG. 7 is a diagram illustrating a portion of a flexible printed circuit board according to various embodiments.

FIG. 8 is a diagram illustrating a portion of a flexible printed circuit board according to various embodiments.

FIG. 9 is a diagram illustrating a portion of a flexible printed circuit board according to various embodiments.

FIG. 10 is a diagram illustrating a portion of a flexible printed circuit board according to various embodiments.

FIG. 11 is an exploded perspective view illustrating a flexible printed circuit board according to various embodiments.

FIG. 12 is a diagram illustrating a ground portion according to various embodiments.

FIG. 13 is a diagram illustrating a magnetic field in a ground portion according to various embodiments.

FIG. 14 is a diagram illustrating a portion of a flexible printed circuit board according to various embodiments.

FIG. 15 is an exploded perspective view of an example electronic device according to various embodiments.

FIGS. 16A, 16B and 16C are diagrams illustrating a portion of a sensor module according to various embodiments.

FIG. 17 includes graphs illustrating the effect of a ground portion according to various embodiments.

FIG. 18 includes graphs illustrating the effect of a ground portion according to various embodiments.

FIG. 19 is an exploded perspective view illustrating a portion of a flexible printed circuit board according to various embodiments.

FIG. 20 includes graphs illustrating the effect of a ground portion according to various embodiments.

Throughout the drawings, similar components, configurations, and/or structures may be given similar reference numerals.

### DETAILED DESCRIPTION

Electronic devices such as smartphones or wearable devices may be equipped with a wireless charging function in consideration of user convenience and functional expandability. The wireless charging function may be implemented such that power is transmitted based on an AC magnetic field generated from a charging pad, and the power is received through a receiving circuit provided inside the electronic device to charge the battery.

Wireless charging technology enables charging without a connection using a connector between an electronic device and an external electronic device, and thus is widely applied in various electronic devices. However, electromagnetic interaction between the AC magnetic field generated during charging and internal components of the electronic device may entail various technical problems.

For example, an electronic device such as a smartphone or a wearable electronic device may include various signal transmission structures, such as a microstrip antenna or a signal line, for implementing a user interface function and a communication function with an external electronic device, and the signal transmission structures may include a ground containing a material having excellent conductivity (e.g., copper). For example, the microstrip antenna may include an antenna pattern, a counter electrode, and a ground for reducing external interference. A signal line configured to transmit health status information in a wearable electronic device may include a ground for stabilizing transmission characteristics and providing an electromagnetic wave shielding effect.

However, a conductive ground reacts to the AC magnetic field during wireless charging to induce an eddy current, and accordingly, a counter magnetic field according to Lenz's law may be formed. The counter magnetic field acts as a reaction to the original magnetic field, thereby acting as an energy loss factor that reduces wireless charging efficiency, and may cause heat generation due to locally occurring temperature rise.

In an electronic device configuration in which a wireless charging function and a communication function are mounted in parallel, induction of eddy current due to a conductive ground may accompany problems such as communication signal interference in addition to a decrease in charging efficiency, thereby negatively affecting overall system performance.

Accordingly, there is a demand for development of technical means capable of reducing or preventing the eddy current caused by a conductive ground and problems resulting therefrom in a wireless charging environment.

An example embodiment may provide an electronic device having two conductive grounds stacked and disposed adjacent to each other, thereby reducing eddy currents caused by conductive grounds.

The following description made with reference to the accompanying drawings may provide an understanding of various example implementations of the disclosure. The various example embodiments include various specific details for the purpose of aiding understanding, but are regarded as example embodiments. One person skilled in the art will understand that various changes and modifications of the various implementations described in the disclosure can be made without departing from the scope and technical spirit of the disclosure. Descriptions of well-known functions and configurations may be omitted for clarity and conciseness.

The terms and words used in the following description and claims are not limited to bibliographical meanings, and may be used to clearly and consistently describe various embodiments. Accordingly, it will be apparent to one skilled in the art that the following description of various embodiments of the disclosure are provided for the purpose of illustration, not for the purpose of limiting the disclosure as defined by the scope of rights and equivalents thereto.

It should be understood that, unless the context clearly indicates otherwise, the singular forms “a,” “an,” and “the” include plural meanings. Accordingly, for example, “component surface” may be understood to include one or more of the surfaces of a component.

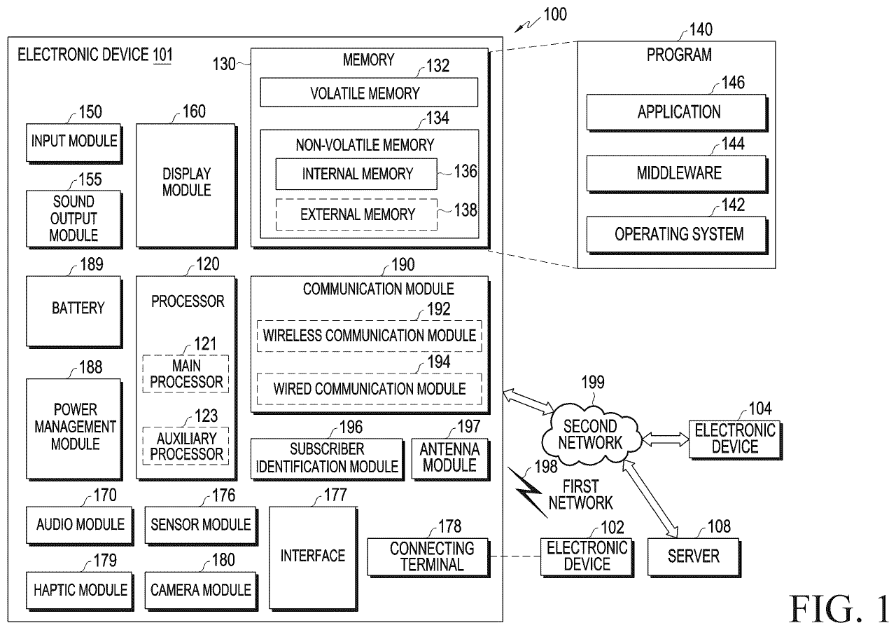

FIG. 1 is a block diagram illustrating an example electronic device 101 in a network environment 100 according to various embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121. Thus, the processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to an embodiment may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used in connection with an embodiment of the disclosure, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

An embodiment as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to an embodiment of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to an embodiment, each component (e.g., a module or a program) of the above-described components may include a single entity or multiple entities, and some of the multiple entities may be separately disposed in different components. According to an embodiment, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to an embodiment, operations performed by the module, the program, or another component may be carried out sequentially, in parallel, repeatedly, or heuristically, or one or more of the operations may be executed in a different order or omitted, or one or more other operations may be added.

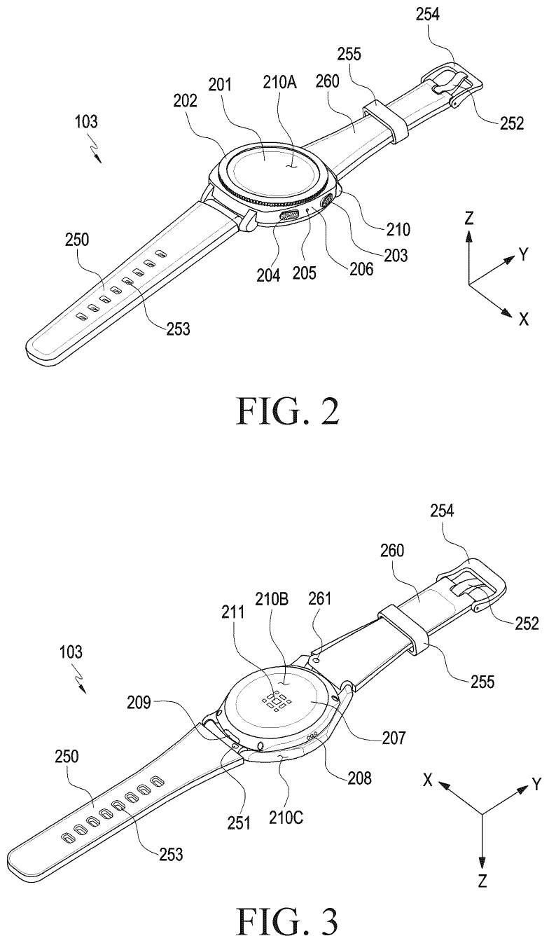

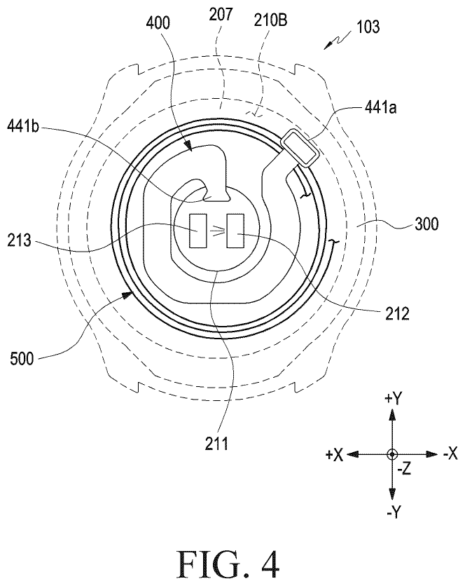

FIG. 2 is a front perspective view illustrating an example electronic device 103 according to various embodiments. FIG. 3 is a rear perspective view illustrating the electronic device 103 of FIG. 2 according to various embodiments.

The embodiments of FIG. 2 and FIG. 3 may be combined with the examples illustrated in FIG. 1 or FIG. 4 to FIG. 20.

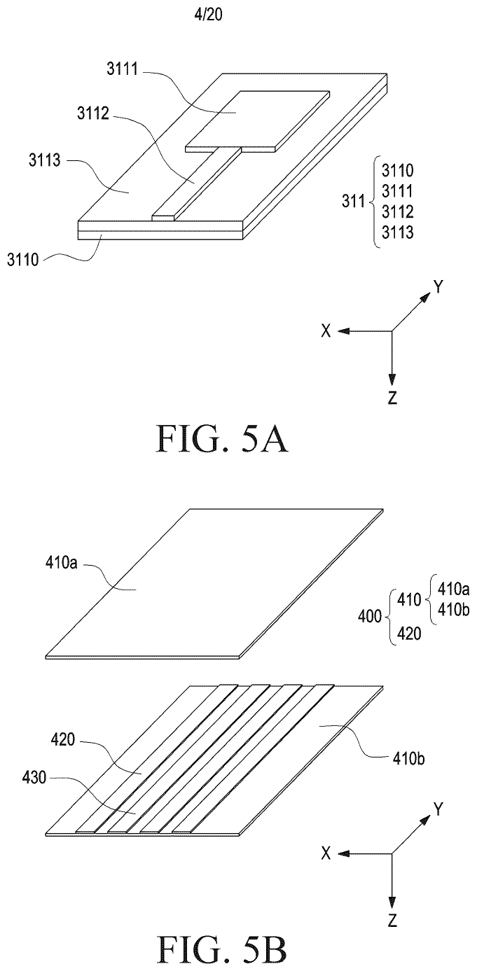

Components described with reference to FIG. 2 and FIG. 3 may be partially or entirely the same as components described with reference to FIG. 1. Components described with reference to FIG. 2 and FIG. 3 may be partially or entirely the same as components described with reference to FIG. 4 to FIG. 20.

In the following detailed description, the length direction, width direction, and/or thickness direction (or height direction) of the electronic device may be mentioned, wherein the length direction may be defined as the “Y-axis direction,” the width direction as the X-axis direction,” and/or the thickness direction as the “Z-axis direction.” In an embodiment, with respect to the direction in which a component is oriented, “negative/positive (−/+)” may be mentioned together with the orthogonal coordinate system illustrated in the drawings. For example, the front surface of the electronic device and/or housing may be defined as “the surface facing the +Z direction,” and the rear surface as “the surface facing the −Z direction.” In an embodiment, a side surface of the electronic device and/or housing may include a region facing the +X direction, a region facing the +Y direction, a region facing the −X direction, and/or a region facing the −Y direction. In an embodiment, “X-axis direction” may refer to including both “−X direction” and “+X direction.” In the following description of the electronic device 103, “first direction” may refer to the −Z-axis direction (or a direction parallel to the −Z-axis), and “second direction” may refer to the +Z-axis direction (or a direction parallel to the +Z-axis).

In the following description of the electronic device 103, the description that a specific component is “disposed on” another component may refer, for example, to the specific component being disposed on the other component in the +Z direction. This is based on the orthogonal coordinate system described in the drawings for the sake of brevity in explanation, and it should be noted that the description of such directions or components does not limit the example embodiment(s) of the disclosure. For example, the orthogonal coordinate system may be defined differently from the disclosure depending on the design specifications of the electronic device or the usage habits of the user.

The description of the electronic device 103 according to an embodiment described with reference to FIG. 1 may be applied substantially identically to the electronic device 103 according to an embodiment described with reference to FIG. 2 and FIG. 3, within the scope in which they do not conflict with each other.

Referring to FIG. 2 and FIG. 3, the electronic device 103 according to an embodiment may include a housing 210. The housing 210 may include a first surface (or front surface) 210A, a second surface (or rear surface) 210B, or a side surface 210C. The side surface 210C may surround a space between the first surface 210A and the second surface 210B.

According to an embodiment, the electronic device 103 may include wearing members 250, 260. The wearing members 250, 260 may be omitted. The wearing members 250, 260 may be connected to at least a portion of the housing 210 and may be configured such that the electronic device 103 is detachably attached to a part of the user's body (e.g., wrist, ankle, etc.).

In an embodiment, the housing 210 may refer to a structure forming some of the first surface 210A of FIG. 2, the second surface 210B of FIG. 3, and the side surfaces 210C. According to an embodiment, the first surface 210A may be formed by a front plate 201 (e.g., a glass plate or polymer plate including various coating layers) that is at least partially substantially transparent. The second surface 210B may be formed by a substantially opaque rear plate 207. In an embodiment, when the electronic device 103 includes a second PCB 211 (or a second PCB including a sensor module) disposed adjacent to the second surface 210B, the rear plate 207 may include a region that is at least partially transparent. The rear plate 207 may be formed by, for example, coated or colored glass, ceramic, polymer, metal (e.g., aluminum, stainless steel (STS), or magnesium), or a combination of at least two of the aforementioned materials. The side surface 210C may be coupled with the front plate 201 and the rear plate 207 and may be formed by a side bezel structure (or “side member”) 206 including metal and/or polymer. In an embodiment, the rear plate 207 and the side bezel structure 206 may be integrally formed and may include the same material (e.g., a metal material such as aluminum). The wearing members 250, 260 may be formed of various materials and shapes. The wearing members 250, 260 may be formed as an integral body or multiple unit links movable relative to each other by woven fabric, leather, rubber, urethane, metal, ceramic, or a combination of at least two of the aforementioned materials.

According to an embodiment, the electronic device 103 may include at least one of a display, an audio module 205, 208 (e.g., the audio module 170 of FIG. 1), a sensor module, a key input device 202, 203, 204 (e.g., the input module 150 of FIG. 1), or a connector hole 209 (e.g., the connection terminal 178 of FIG. 1). In an embodiment, the electronic device 103 may omit at least one of the components (e.g., the key input device 202, 203, 204, the connector hole 209, or the sensor module) or may additionally include another component.

According to an embodiment, the audio module 205, 208 may include a microphone hole 205 and a speaker hole 208. The microphone hole 205 may have a microphone disposed therein for acquiring external sounds, and in an embodiment, multiple microphones may be disposed to detect the direction of sounds. The speaker hole 208 may be used as an external speaker and a receiver for calls. In an embodiment, a speaker may be included without a speaker hole (e.g., a piezo speaker).

According to an embodiment, the second PCB 211 may include a sensor module on one surface thereof. According to an embodiment, the sensor module may generate an electrical signal or data value corresponding to the operating state inside the electronic device 103 or the external environmental state. The sensor module may include, for example, a biometric sensor module (e.g., heart rate measurement (HRM) sensor) disposed on the second surface 210B of the housing 210. The electronic device 103 may further include a sensor module not shown, for example, at least one of a gesture sensor, a gyro sensor, a barometric pressure sensor, a magnetic sensor, an acceleration sensor, a grip sensor, a color sensor, an infrared (IR) sensor, a biometric sensor, a temperature sensor, a humidity sensor, or an illuminance sensor.

According to an embodiment, the key input device 202, 203, 204 may include a wheel key 202 disposed on the first surface 210A of the housing 210 and rotatable in at least one direction, and/or side key buttons 203, 204 disposed on the side surface 210C of the housing 210. The wheel key 202 may have a shape corresponding to the shape of the front plate 201. In an embodiment, the electronic device 103 may not include some or all of the aforementioned key input devices 202, 203, 204, and the key input devices 202, 203, 204 that are not included may be implemented on the display in another form such as soft keys. The connector hole 209 may accommodate a connector (e.g., a USB connector) for transmitting/receiving power and/or data with an external electronic device, and may include another connector hole (not shown) capable of accommodating a connector for transmitting/receiving audio signals with an external electronic device. The electronic device 103 may further include, for example, a connector cover (not shown) that covers at least a portion of the connector hole 209 and blocks inflow of external foreign substances into the connector hole.

According to an embodiment, the wearing members 250, 260 may be detachably attached to at least a partial region of the housing 210 using locking members 251, 261. The locking members 251, 261 may include, for example, a binding component such as a pogo pin, and depending on the embodiment, may be replaced with protrusion(s) or recess(es) formed on the wearing members 250, 260. For example, the wearing members 250, 260 may be coupled so as to engage with a recess or protrusion formed on the housing 210. The wearing members 250, 260 may include one or more of a fixing member 252, a fixing member fastening hole 253, a band guide member 254, and a band fixing ring 255.

According to an embodiment, the fixing member 252 may be configured to fix the housing 210 and the wearing members 250, 260 to a part of the user's body (e.g., wrist, ankle, etc.). The fixing member fastening hole 253 may fix the housing 210 and the wearing members 250, 260 to a part of the user's body in correspondence with the fixing member 252. The band guide member 254 may be configured to limit the range of movement of the fixing member 252 when the fixing member 252 is fastened to the fixing member fastening hole 253, thereby enabling the wearing members 250, 260 to be closely attached to a part of the user's body. The band fixing ring 255 may limit the range of movement of the wearing members 250, 260 in a state where the fixing member 252 and the fixing member fastening hole 253 are fastened.

FIG. 4 is a diagram illustrating various components included in an electronic device according to various embodiments.

The example illustrated in FIG. 4 may be combined with the examples of FIG. 1 to FIG. 3 or FIG. 5 to FIG. 20.

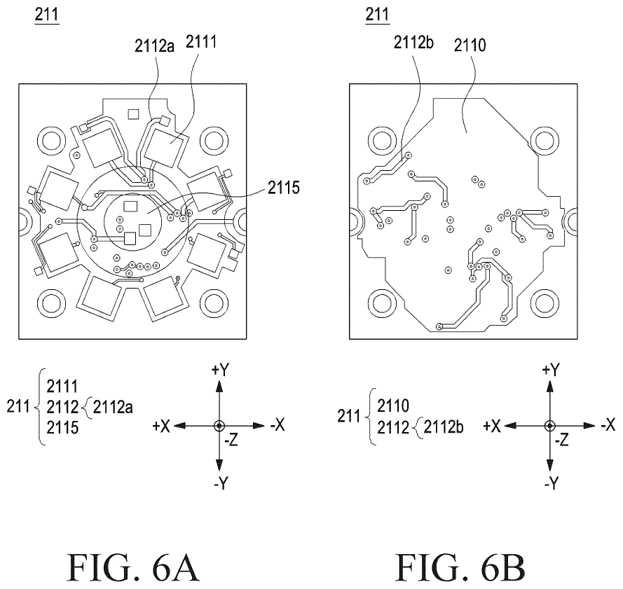

Components described with reference to FIG. 4 may be partially or entirely the same as components described with reference to FIG. 1 to FIG. 3. Components described with reference to FIG. 4 may be partially or entirely the same as components described with reference to FIG. 5 to FIG. 20.

The housing (e.g., the housing 210 of FIG. 2 and FIG. 3) of the electronic device 103 according to an embodiment may include a plate 207 (e.g., a rear plate). The plate 207 may include a surface facing the first direction (e.g., the rear surface 210B of FIG. 2 and FIG. 3). For example, in case that the electronic device 103 corresponds to the wearable electronic device of FIG. 2 and FIG. 3, the surface of the plate 207 (e.g., the rear surface 210B of FIG. 2 and FIG. 3) may include at least one substantially transparent region (e.g., a transparent plate and/or window) configured such that light generated from an optical element unit (e.g., a light-emitting unit 212 of a sensor module included in the second PCB 211) disposed inside the housing is emitted to the outside, and light reflected by an external object (e.g., a user's finger) and received is incident on a light-receiving unit 213.

The electronic device 103 may include various components disposed adjacent to the surface (e.g., the rear surface 210B) of the plate 107. For example, the electronic device 103 may include a wireless charging coil 500 disposed adjacent to the plate 207 in a second direction opposite to the first direction and configured to transmit and/or receive power with respect to an external electronic device or a wireless power transmission device.

According to one embodiment, the electronic device 103 may include a first PCB and a second PCB 211. According to one embodiment, the first PCB may be referred to as a “main PCB.” According to one embodiment, the second PCB 211 may be referred to as a “sub PCB.” According to one embodiment, the second PCB 211 may alternatively be referred to as a “sensor board.”

According to one embodiment, the first PCB may convert an alternating current(AC) received from the wireless charging coil 500 into a direct current(DC). According to one embodiment, the electronic device 103 may include a flexible printed circuit board 400 to transmit the alternating current received from the wireless charging coil 500 from the wireless charging coil 500 to the first PCB.

According to one embodiment, the first PCB may include a first ground plane. According to one embodiment, the first ground plane may be used as a reference potential for electronic components mounted on the first PCB.

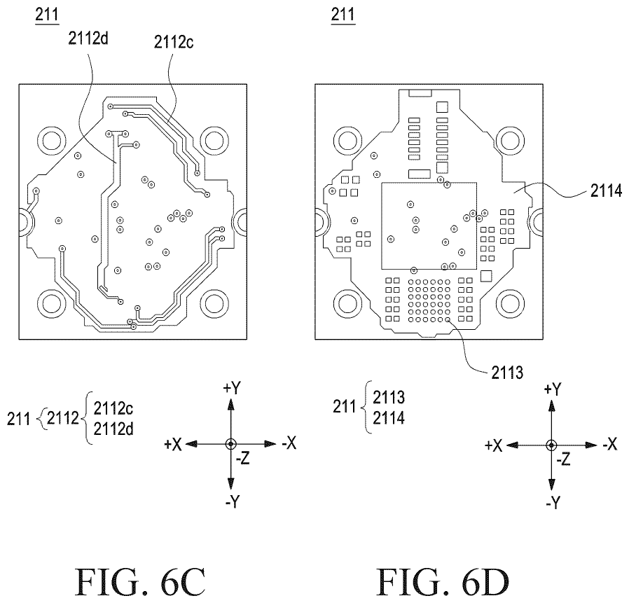

According to one embodiment, the second PCB 211 may include a second ground plane. According to one embodiment, the second ground plane may be used as a reference potential for a sensing member (e.g., the sensing member 2110 of FIG. 6) or an auxiliary circuit disposed on the second PCB 211.

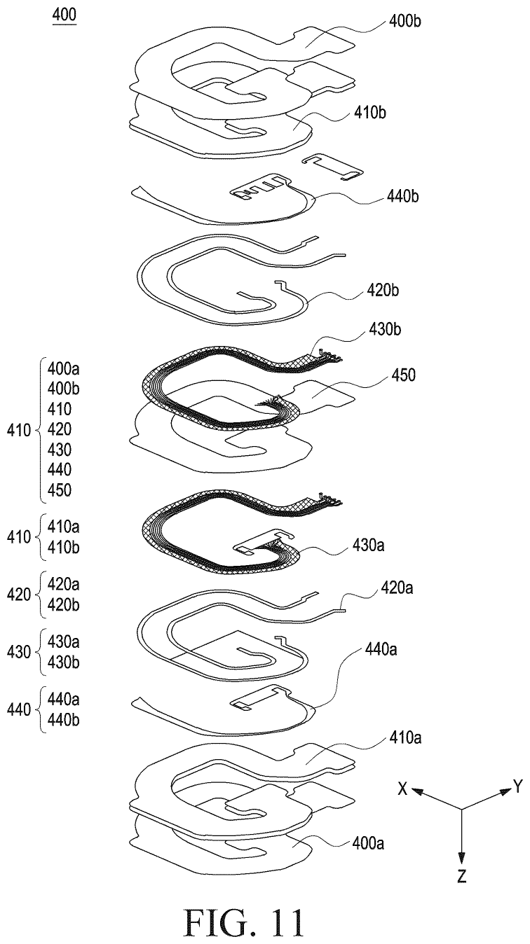

According to one embodiment, the flexible printed circuit board 400 may include a ground portion (e.g., the ground portion 410 of FIG. 11). According to one embodiment, the ground portion (e.g., the ground portion 410 of FIG. 11) formed on the flexible printed circuit board 400 may be electrically connected to the first ground plane and/or the second ground plane.

Referring to FIG. 4, the electronic device 103 according to an embodiment may include a support bracket 300. The support bracket 300 may function as a structure for supporting components inside the electronic device 103. The support bracket 300 may be disposed inside the housing (e.g., the housing 210 of FIG. 2). As one example, the wireless charging coil 500 and the second PCB 211 of the electronic device 103 may be disposed on the support bracket 300.

The electronic device 103 according to an embodiment may include a wireless charging coil 500. The wireless charging coil 500 may be disposed inside the electronic device 103. As one example, the wireless charging coil 500 may be disposed inside the rear surface 210B of the electronic device 103. As an example, the wireless charging coil 500 may be disposed inside the rear surface 210B of the electronic device (e.g., the electronic device 103 of FIG. 1 and/or the electronic device 103 of FIG. 2 and FIG. 3) while being disposed on the support bracket 300. The second PCB 211 may be disposed, inside the rear surface 210B of the electronic device 103, in a position in which the same is at least partially surrounded by the wireless charging coil 500 when viewed from above (e.g., when viewed along the Z-axis).

In the illustrated example, the second PCB 211 is shown, by way of example, as being disposed on an inner side of a rear surface 210B of the electronic device 103 and as being at least partially surrounded by the wireless charging coil 500 when viewed from above (e.g., when viewed along a Z-axis). However, one end of the wireless charging coil 500 may be electrically connected to the second PCB 211.

According to one embodiment, the wireless charging coil 500 and/or the second PCB 211 may be electrically connected to a connector included in the flexible printed circuit board 400 (e.g., a second bonding member 441b). According to one embodiment, a current received from the wireless charging coil 500 may be transmitted to the first PCB through the flexible printed circuit board 400.

According to an embodiment, a shielding sheet may be disposed in the first direction of the wireless charging coil 500 and in the second direction of the above-described housing (e.g., the rear plate 207 of FIG. 2), and configured to overlap with the wireless charging coil 500 when viewed from the first direction, thereby blocking electromagnetic interference (EMI) from the wireless charging coil 500 or preventing/reducing internally generated electromagnetic waves from leaking to the outside.

According to an embodiment, the electronic device 103 may include an electronic component. For example, the electronic component may include various components such as at least one processor or a battery. The electronic device 103 may include a flexible printed circuit board 400, or another electronic component connected to the electronic component and/or the wireless charging coil 500 through the flexible printed circuit board 400. In this regard, the electronic component and the other electronic component may be referred to as “first electronic component” and “second electronic component,” respectively, for convenience of distinction. For example, the other electronic component (e.g., the second electronic component) may include an antenna and/or a sensor module. According to an embodiment, the other electronic component (e.g., the second electronic component) may be disposed on substantially the same plane as the wireless charging coil 500. According to an embodiment, a ring-shaped wireless charging coil 500 may be disposed so as to surround the other electronic component (e.g., the second electronic component). According to an embodiment, the other electronic component (e.g., the second electronic component) may be configured to be at least partially surrounded by the wireless charging coil 500. For example, the other electronic component (e.g., the second electronic component) may be disposed at the center portion of the wireless charging coil 500. For example, in case that the electronic device 103 is a wearable electronic device such as in FIG. 2 and FIG. 3, the other electronic component (e.g., the second electronic component) may include a sensor module (e.g., a heart rate measurement (HRM) sensor). For example, the HRM sensor may refer to a sensor that measures heart rate using a photoplethysmography (PPG) technique. As another example, in case that the electronic device 103 is a bar-type electronic device such as a smartphone, the other electronic component (e.g., the second electronic component) may be antennas for transmitting/receiving signals with an external electronic device or a wireless power transmission device.

According to an embodiment, the other electronic component (e.g., the second electronic component) may include a substrate. In case that the electronic device 103 is a wearable electronic device such as in FIG. 2 and FIG. 3, the sensor module included in the second PCB 211 may include a light-emitting unit 212 and a light-receiving unit 213 disposed on the substrate. For example, each of the light-emitting unit 212 and/or the light-receiving unit 213 may be provided in plurality, and may be disposed in various types depending on the embodiment. According to an embodiment, the flexible printed circuit board 400 may electrically connect the electronic component (e.g., the first electronic component) and the other electronic component (e.g., the second electronic component). According to an embodiment, the flexible printed circuit board 400 may be electrically connected to the electronic component (e.g., the first electronic component) through a first PCB. According to one embodiment, the flexible printed circuit board 400 may be electrically connected to another electronic component (e.g., a second electronic component) via the second PCB.

According to an embodiment, the flexible printed circuit board 400 may electrically connect the first PCB to the first electronic component, and may electrically connect the second PCB 211 to the second electronic component. According to an embodiment, a connector (e.g., a second bonding member 441b) at one end of the flexible printed circuit board 400 may be connected to the second PCB 211, and a connector (e.g., a first bonding member 441a) at the other end of the flexible printed circuit board 400 may be electrically connected to the first PCB.

According to an embodiment, the connector connected to the first PCB may be named a “first connector,” and the connector connected to the second PCB may be named a “second connector.”

The flexible printed circuit board 400 may electrically connect the electronic component (e.g., the first electronic component) and the wireless charging coil 500. According to an embodiment, a connector (e.g., a second bonding member 441b) at one end of the flexible printed circuit board 400 may be connected to the wireless charging coil 500 or the second electronic component, and the flexible printed circuit board 400 extends from the inside to the outside of the wireless charging coil 500 so as to be connected to the first electronic component (e.g., the processor and/or the battery) through a connector (e.g., a first bonding member 441a) at the other end of the flexible printed circuit board 400.

The connector (e.g., the second bonding member 441b) at one end of the flexible printed circuit board 400 may be omitted. For example, the flexible printed circuit board 400 may be integrated with the second PCB 211.

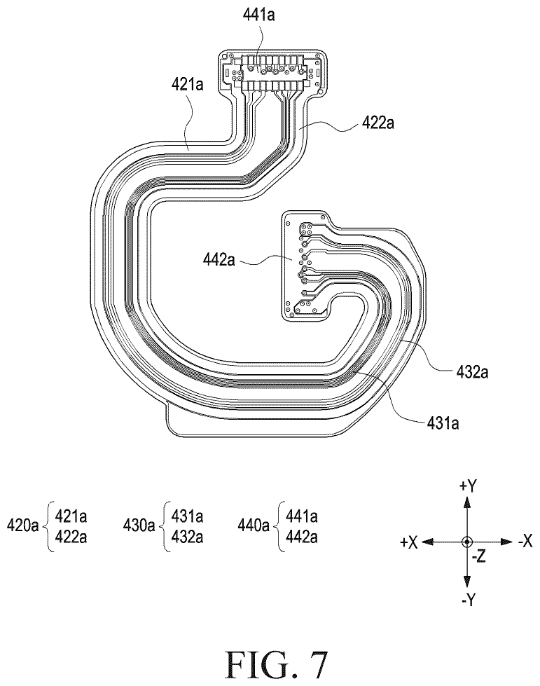

According to an embodiment, plurality of conductive lines may be disposed between the first bonding member 441a and the second bonding member 441b. According to an embodiment, the plurality of conductive lines may include a power line (e.g., the power line 420 of FIG. 7) and a signal line (e.g., the signal line 430 of FIG. 7), which will be described later. According to one embodiment, the plurality of conductive lines may be configured to electrically connect a first bonding member 441a and a second bonding member 441b.

According to one embodiment, the plurality of conductive lines may include a ground line. According to one embodiment, when a ground portion (e.g., the ground portion 410 of FIG. 11) formed on the flexible printed circuit board 400 is electrically connected to a first ground plane or a second ground plane, a reference potential between the first ground plane and the second ground plane may be maintained to be the same or a potential difference therebetween may be reduced through the ground line.

At least two of the plurality of conductive lines may be used as AC power transmission lines for supplying AC power received through the wireless charging coil 500 to the first PCB. The AC power transmission lines may be disposed so as to overlap with a ground portion (to be described later) when viewed from the first direction.

According to an embodiment, an electronic component (e.g., first electronic component) and the wireless charging coil 500 may be connected without a separate flexible printed circuit board 400.

According to an embodiment, the wireless charging coil 500 may be formed in a flat coil shape and may generate a current by electromagnetic induction generated from an external electronic device (e.g., a wireless power transmission/reception device). The electronic device 500 may charge a battery (not shown) embedded in the electronic device 500 using the current generated in a wireless charging antenna including the wireless charging coil 500.

According to an embodiment, in case that the first electronic component is a battery or a component connected to a battery, AC power received through the wireless charging coil 500 may be converted into DC power through the first electronic component to charge the battery.

According to an embodiment, in case that the other electronic component (e.g., the second electronic component) is a sensor module, the flexible printed circuit board 400 may be configured to include at least one signal line for transferring a signal corresponding to information sensed through the sensor module.

FIGS. 5A and 5B are perspective views illustrating a portion of an antenna module and a flexible printed circuit board according to various embodiments.

The embodiment of FIGS. 5A and 5B may be combined with the embodiments of FIG. 1 to FIG. 4 or FIG. 6 to FIG. 20.

Components described with reference to FIGS. 5A and 5B may be partially or entirely the same as components described with reference to FIG. 1 to FIG. 4. Components described with reference to FIGS. 5A and 5B may be partially or entirely the same as components described with reference to FIG. 6 to FIG. 20.

According to an embodiment, the antenna module 311 may include a ground portion 3110, an antenna 3111, a connection portion 3112, and a substrate 3113. According to an embodiment, the ground portion 3110 may form a reference potential of the antenna module 311, secure electrical stability of internal circuits, and reduce influence from external electromagnetic interference (EMI).

For example, the ground portion 3110 may be formed of a metal material having excellent conductivity (e.g., copper or aluminum) in order to protect the circuit from signal noise that may occur during operations of the antenna 3111 and/or the connection portion 3112 included in the antenna module 311 or from high-frequency interference introduced from the outside.

According to an embodiment, as the ground portion 3110 is formed of a metal material having excellent conductivity, an eddy current may be formed in the ground portion 3110 due to an AC magnetic field, and this may reduce wireless charging efficiency. In an embodiment, the ground portion 3110 may include two ground layers electrically spaced apart in the first direction (e.g., the −Z-axis direction), thereby reducing degradation of wireless charging efficiency.

According to an embodiment, the ground portion 3110 may be disposed in the second direction (e.g., the +Z-axis direction) of the antenna 3111 and the substrate 3113, thereby forming the lower structure of the antenna module 311 and shielding electromagnetic waves.

In FIG. 5, although the ground portion 3110 is illustrated as being formed in a single layer by way of example, the ground portion 3110 may include two ground layers that are stacked in the first direction (e.g., the −Z-axis direction) and electrically spaced apart from each other, as will be described in greater detail below.

According to an embodiment, the antenna 3111 may transmit/receive electromagnetic waves to/from an external electronic device and/or a wireless power transmission/reception device. According to an embodiment, the antenna 3111 may be configured to perform wireless communication with an external electronic device and/or a wireless power transmission/reception device.

The antenna 3111 is disposed in the first direction (e.g., the −Z-axis direction) of the substrate 3113, thereby forming the upper structure of the antenna module 311. Accordingly, the antenna 3111 may be disposed adjacent to an external surface and may be configured to smoothly transmit/receive radio signals.

According to an embodiment, radio signals received through the antenna 3111 may be processed through an internal circuit or may be transmitted to a connected circuit such as the flexible printed circuit board 400 through the connection portion 3112.

According to an embodiment, the connection portion 3112 may supply power to the antenna 3111 or electrically transfer received data, and may also be configured to transfer signals to the antenna 3111.

According to an embodiment, the connection portion 3112 may be formed of a metal having excellent conductivity (e.g., copper or aluminum). For example, the connection portion 3112 may further include an insulating layer and a shielding layer to reduce interference with adjacent circuits. The connection portion 3112 may be disposed along the inside or outside of the substrate 3113 and may be designed in consideration of space efficiency.

According to an embodiment, the substrate 3113 may be a structure for supporting various components such as the ground portion 3110, the antenna 3111, and the connection portion 3112 of the antenna module 311.

According to an embodiment, the substrate 3113 may be disposed between the ground portion 3110 and the antenna 2111. In addition, the substrate 3113 may enable other components to be stably disposed to withstand external vibrations and/or impacts, and may also provide an electrical connection path by embedding or supporting power lines or the like.

According to an embodiment, the substrate 3113 may be formed of a material having insulating properties (e.g., polyimide or liquid crystal polymer) to prevent/reduce interference between circuits, and may also be utilized as a heat dissipation structure that efficiently dissipates heat generated in the antenna module 311 to the outside through a material to which thermal conductivity is imparted as necessary. In addition, the substrate 3113 may include a connection portion 3112 to enable electrical connection between the antenna module 311 and an external circuit (e.g., the flexible printed circuit board 400).

In FIGS. 5A and 5B, although configurations are described using an antenna as an example of the second electronic component (e.g., an antenna or a sensor module), the description is not limited thereto, and the description of the antenna module 311 may also be applied to a sensor module to be described later (e.g., a sensor module included in the second PCB 211 of FIG. 6).

According to an embodiment, the flexible printed circuit board 400 may include a ground portion 410 and a signal line 430.

According to an embodiment, the ground portion 410 may include a first ground portion 410a configured to form the upper structure of the flexible printed circuit board 400, and a second ground portion 410b disposed in the second direction (e.g., the +Z-axis direction) of the flexible printed circuit board 400 and configured to form the lower structure of the flexible printed circuit board 400.

According to an embodiment, the ground portion 410 may form a reference potential of the flexible printed circuit board 400, secure electrical stability of internal circuits, and reduce influence from external electromagnetic interference (EMI).

For example, the ground portion 410 may be formed of a metal material having excellent conductivity (e.g., copper or aluminum) in order to protect the circuit from signal noise that may occur during operation of the signal line 430 or from high-frequency interference introduced from the outside.

According to an embodiment, an eddy current may be formed in the ground portion 410 due to an AC magnetic field, and this may reduce wireless charging efficiency.

According to an embodiment, the ground portion 410 may include two ground layers electrically spaced apart in the first direction (e.g., the −Z-axis direction), thereby reducing degradation of wireless charging efficiency.

According to an embodiment, the ground portion 410 may be disposed in the first direction (e.g., the −Z-axis direction) and the second direction (e.g., the +Z-axis direction) of the signal line 430 and may be configured to shield electromagnetic waves generated from the signal line 430.

According to an embodiment, the signal line 430 may be disposed between ground portions 410. According to an embodiment, the signal line 430 may be configured to transfer radio signals received through the antenna 311 to the first electronic component. According to an embodiment, the signal line 430 may be configured to transfer biometric signals (e.g., heart rate, skin conductivity), pressure, temperature, or motion data received from a sensing member to be described later (e.g., the sensing member 2111 of FIG. 6) to the first electronic component.

In this example, although the first ground portion 410a and the second ground portion 410b are illustrated as being formed in a single layer by way of example, this is an example for aiding understanding, and in practice, as will be described later, the first ground portion 410a and the second ground portion 410b may include two ground layers electrically spaced apart in the first direction (e.g., the −Z-axis direction).

In this example, although the ground portions 410, power lines 410, and/or signal lines 430 are illustrated in specific shapes, the disclosure is not limited thereto, and the same may be configured in various pattern forms. The same may further include power lines 420, signal lines 430, and other components of FIG. 7 (described in greater detail below).

FIGS. 6A, 6B, 6C and 6D are diagrams illustrating a portion of a second PCB according to various embodiments.

FIG. 6A to FIG. 6D may be combined with the FIG. 1 to FIG. 5B and/or FIG. 7 to FIG. 20.

Components described with reference to FIG. 6A to FIG. 6D may be partially or entirely the same as components described with reference to FIG. 1 to FIG. 5B. Components described with reference to FIG. 6A to FIG. 6D may be partially or entirely the same as components described with reference to FIG. 7 to FIG. 20.

According to an embodiment, FIG. 6A may be a diagram illustrating a first layer of the second PCB 211, FIG. 6B may be a diagram illustrating a second layer of the second PCB 211, FIG. 6C may be a diagram illustrating a third layer of the sensor module 211, and FIG. 6D may be a diagram illustrating a fourth layer of the second PCB 211. The first to fourth layers of the second PCB 211 may be sequentially stacked in the second direction (e.g., the +Z-axis direction).

According to an embodiment, the second PCB 211 may include a ground portion 2110, a sensing member 2111, sensor module power lines 2112a, 2112b, 2112c, 2112d, a connection portion 2113, a metal layer 2114, and/or an optical element portion 2115 (e.g., the light-emitting unit 212 and the light-receiving unit 213 of FIG. 4).

According to an embodiment, the ground portion 2110 may provide signal interference prevention/reduction and an electrical reference potential as described above. In addition, the ground portion 2110 may be disposed on the second layer so as to reduce electromagnetic interference generated from circuit elements disposed on upper and lower layers.

According to an embodiment, multiple sensing members 2111 may be included, and each sensing member 2111 may be disposed on the same plane (e.g., the first layer). For example, the multiple sensing members 2111 may be disposed in a circular shape to collect external information from multiple directions with reference to a specific center point.

According to an embodiment, the structure in which the sensing member 2111 is disposed may be suitable for a wearable electronic device or a smartphone or other electronic device having a curved surface or a specific direction, and may enable more precise environmental recognition. The sensing member 2111 may be configured to collect data such as temperature, humidity, or biometric signals, for example.

According to an embodiment, the sensor module power lines 2112a, 2112b, 2112c, 2112d may be disposed on first to fourth layers. For example, the sensor module power lines 2112a, 2112b, 2112c, 2112d may supply power to the sensing member 2111 and may form a path for transferring collected signals to an external circuit through the connection portion 2113.

According to an embodiment, a metal layer 2114 may be disposed on the fourth layer together with the connection portion 2113, and at least a portion of the metal layer 2114 may have a configuration in which the connection portion 2113 is formed. For example, the metal layer 2114 may include a ground region. For example, the metal layer 2114 may be disposed inside an insulating layer (e.g., a coverlay layer) of the second PCB 211.

According to an embodiment, the connection portion 2113 may be electrically connected to an external circuit board (e.g., the second PCB 211) to enable signal and power transfer between the sensor module and an electronic component (e.g., a processor).

Although it is assumed in this illustration that the ground portion 2110 is disposed on the second layer, the sensor member 2111 is disposed in the first direction (e.g., the −Z-axis direction) of the second layer, and the ground portion 2110 accordingly protects internal electronic components from signal noise generated from the sensor member 2111, the disclosure is not limited thereto. For example, the ground portion 2110 may be disposed on various layers as long as it can be disposed in the first direction (e.g., the −Z-axis direction) of the sensor member 2111.

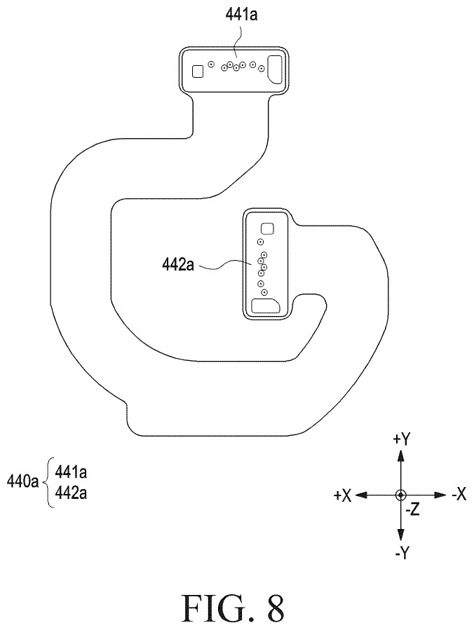

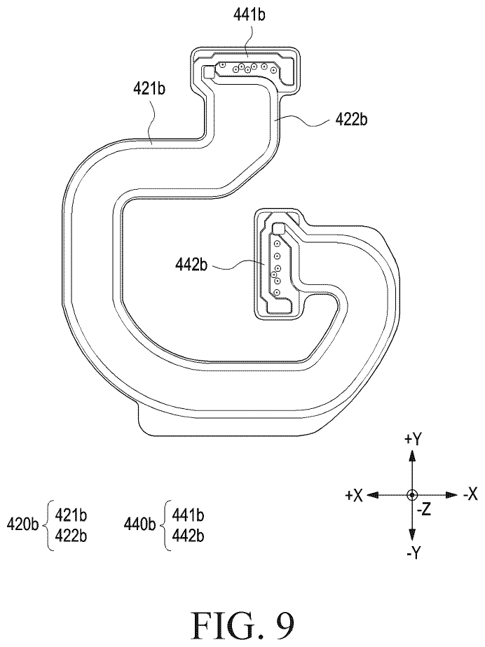

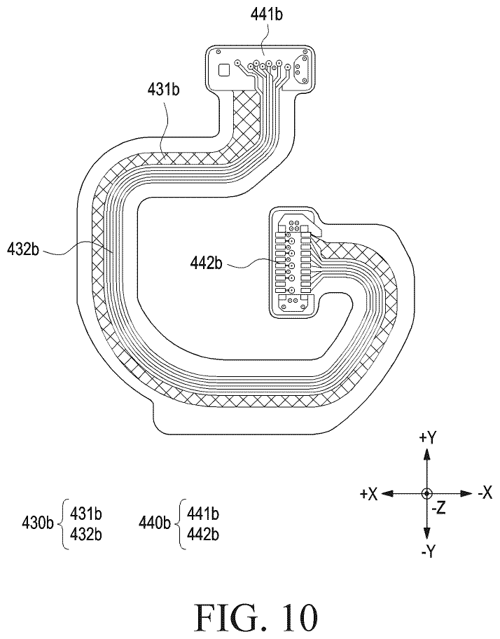

FIG. 7 is a diagram illustrating a portion of a flexible printed circuit board according to various embodiments. FIG. 8 is a diagram illustrating a portion of a flexible printed circuit board according to various embodiments. FIG. 9 is a diagram illustrating a portion of a flexible printed circuit board according to various embodiments. FIG. 10 is a diagram illustrating a portion of a flexible printed circuit board according to various embodiments. FIG. 11 is an exploded perspective view illustrating a flexible printed circuit board according to various embodiments.

The embodiments of FIG. 7 to FIG. 11 may be combined with the embodiments of FIG. 1 to FIG. 6D or FIG. 12 to FIG. 20.

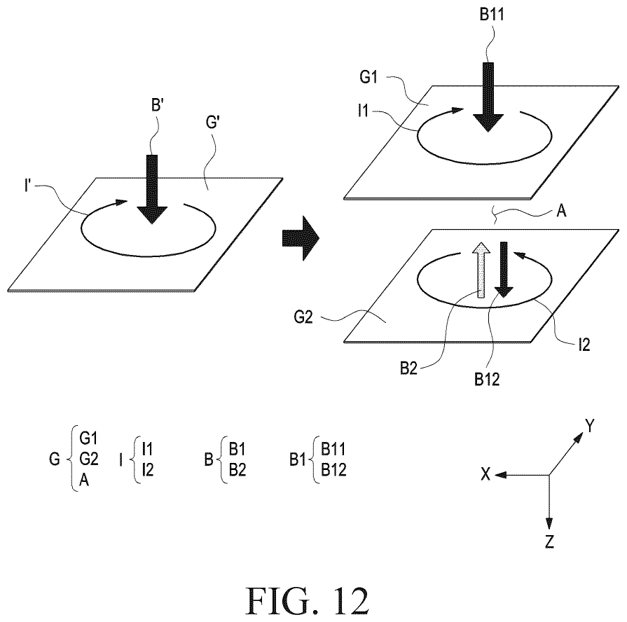

Components described with reference to FIG. 7 to FIG. 11 may be partially or entirely the same as components described with reference to FIG. 1 to FIG. 6D. Components described with reference to FIG. 7 to FIG. 11 may be partially or entirely the same as components described with reference to FIG. 12 to FIG. 20.

According to an embodiment, the flexible printed circuit board 400 may be disposed inside the electronic device 103. For example, the flexible printed circuit board 400 may have a structure in which the same is bent multiple times. The flexible printed circuit board 400 may include multiple conductive layers.

According to an embodiment, the flexible printed circuit board 400 may include a first protective member 400a, a second protective member 400b, a ground portion 410, a power line 420, a signal line 430, a bonding member 440, and/or an insulating layer 450.

Referring to FIG. 11, the first protective member 400a and the second protective member 400b may be configured to form the external appearance of the flexible printed circuit board 400, thereby protecting the flexible printed circuit board 400. According to an embodiment, the first protective member 400a and the second protective member 400b may be named “insulating members” or “insulating coatings.”

According to an embodiment, the first protective member 400a may be disposed on the outermost side in the second direction (e.g., the +Z-axis direction) of the flexible printed circuit board 400, that is, on the upper surface thereof, and the second protective member 400b may be disposed on the outermost side in the first direction (e.g., the −Z-axis direction) of the flexible printed circuit board 400, that is, on the lower surface thereof.

According to an embodiment, the protective members 400a, 400b may protect internal circuit configurations (e.g., the power line 420 or the signal line 430) of the flexible printed circuit board 400 from the external environment. The first protective member 400a and the second protective member 400b have structures for covering the outside of the first ground portion 410a and the second ground portion 410b, and may supplement the mechanical rigidity of the flexible printed circuit board 400. As one example, the protective members 400a, 400b may include a silicone resin, polyimide (PI), or an epoxy-based insulating resin.

Referring to FIG. 11, the ground portion 410 may include a first ground portion 410a and a second ground portion 410b. The first ground portion 410a may be disposed in the second direction (e.g., the +Z-axis direction, lower side) of the flexible printed circuit board 400, and the second ground portion 410b may be disposed in the first direction (e.g., the −Z-axis direction, upper side) thereof.

According to an embodiment, the ground portion 410 may be configured to shield electromagnetic interference that may be generated from the signal line 430 and the power line 420, and to act as a shielding layer that suppresses electromagnetic noise from the outside, thereby securing stability of the overall system.

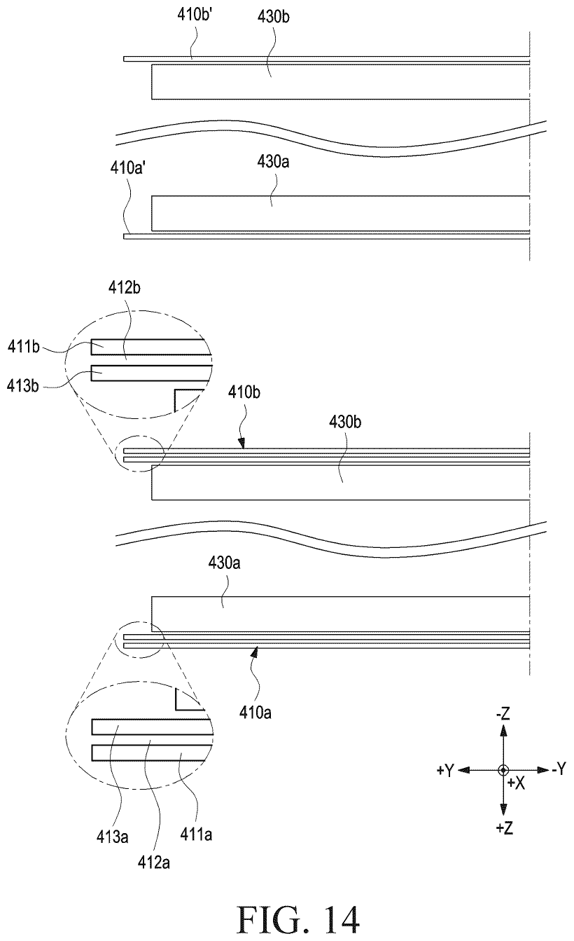

According to an embodiment, the first ground portion 410a and/or the second ground portion 410b may each be formed in a multilayer structure including at least two conductive metal layers (e.g., the (1-1)^{th} ground layer 411a and the (1-2)^{th} ground layer 413a of FIG. 14) and an insulating layer (e.g., the first insulating layer 412a of FIG. 14) interposed therebetween.

According to an embodiment, as the first ground portion 410a and the second ground portion 410b are formed in a multilayer structure, generation of an eddy current that may be induced inside the ground portion 410 may be reduced, and degradation of wireless charging efficiency that may occur due to the eddy current may be reduced.

According to an embodiment, the flexible printed circuit board 400 may include multiple metal layers, and the multiple metal layers may be configured to form a ground or to form a signal pattern. According to an embodiment, multiple first ground portions 410a and/or second ground portions 410b may be ground layers formed of continuous metal layers among multiple layers of the flexible printed circuit board 400. The first ground portion 410a and/or the second ground portion 410b of the flexible printed circuit board 400 may be disposed on metal layers located on the outside of the upper side (e.g., the first direction, the −Z-axis direction) and the lower side (e.g., the second direction, the +Z-axis direction) of the flexible printed circuit board 400.

According to an embodiment, as described above, power loss due to eddy current accumulates within the ground portion 410 may cause significant heat generation and power loss of the flexible printed circuit board 400, and the structure according to an embodiment may effectively improve such problems.

According to an embodiment, the first ground portion 410a and the second ground portion 410b may be disposed on the upper side (e.g., the first direction, the −Z-axis direction) and the lower side (e.g., the second direction, the +Z-axis direction) of the flexible printed circuit board 400, and may be located adjacent to the protective members 400a, 400b. Accordingly, not only external electromagnetic noise but also the possibility of damage due to external physical contact may be reduced, and the durability of the entire circuit may also be improved.

According to an embodiment, the power line 420 may include a first power line 420a and/or a second power line 420b. According to an embodiment, the signal line 430 may include a first signal line 430a and/or a second signal line 430b. According to an embodiment, the bonding member 440 may include a first bonding member 440a and/or a second bonding member 440b.

Referring to FIG. 11, the first power line 420a, the first signal line 430a, and the first bonding member 440a may be disposed in the second direction (e.g., the +Z-axis direction) of the insulating layer 450. According to an embodiment, the first power line 420a, the first signal line 430a, and the first bonding member 440a may be disposed between the insulating layer 450 and the first ground portion 410a.

The first power line 420a, the first signal line 430a, and the first bonding member 440a may form one conductive layer configured to transmit and/or receive power and signals. According to an embodiment, the first power line 420a and the first signal line 430a may be bonded by the first bonding member 440a.

Referring to FIG. 7 and FIG. 8, the first power lines 421a, 422a, the first signal lines 431a, 432a, and the first bonding members 441a, 442a may be disposed on the same plane and, when viewed from the first direction (e.g., the −Z-axis direction), the first signal lines 431a, 432a may be disposed inside the first power lines 421a, 422a.

Although it is assumed, as an example, in this illustration and the embodiments below that, when viewed from the first direction (e.g., the −Z-axis direction), the first signal lines 431a, 432a are disposed inside the first power lines 421a, 422a, the disclosure is not limited thereto. For example, the first power lines 421a, 422a and the first signal lines 431a, 432a may not overlap each other, and when viewed from the first direction (e.g., the −Z-axis direction), may be independently disposed at locations spaced apart from each other along the width direction (e.g., the −X-axis direction) of the flexible printed circuit board 400, for example, at both edges thereof.

Referring to FIG. 11, the second power line 420b, the second signal line 430b, and the second bonding member 440b may be disposed in the first direction (e.g., the −Z-axis direction) of the insulating layer 450. According to an embodiment, the second power line 420b, the second signal line 430b, and the second bonding member 440b may be disposed between the insulating layer 450 and the second ground portion 410b.

The second power line 420b, the second signal line 430b, and the second bonding member 440b may form one conductive layer configured to transmit and/or receive power and signals. According to an embodiment, the second power line 420b and the second signal line 430b may be bonded by the second bonding member 440b.

Referring to FIG. 9 and FIG. 10, the second power lines 421b, 422b, the second signal lines 431b, 432b, and the second bonding members 441b, 442b may be disposed on the same plane and, when viewed from the first direction (e.g., the −Z-axis direction), the second signal lines 431b, 432b may be disposed inside the second power lines 421b, 422b.

Although it is assumed, as an example, in this illustration and the embodiments below that, when viewed from the first direction (e.g., the −Z-axis direction), the second signal lines 431b, 432b are disposed inside the second power lines 421b, 422b, the disclosure is not limited thereto. For example, the second power lines 421b, 422b and the second signal lines 431b, 432b may not overlap each other, and when viewed from the first direction (e.g., the −Z-axis direction), may be independently disposed at locations spaced apart from each other along the width direction (e.g., the −X-axis direction) of the flexible printed circuit board 400, for example, at both edges thereof.

Although it is assumed, as an example, in this illustration and the embodiments below that at least one power line 420 and signal line 430 form the same plane, and two conductive layers forming the same plane are formed on both sides with respect to the insulating layer 450, the disclosure is not limited thereto. For example, at least one power line 420 and signal line 430 may form the same plane, and one may be disposed within the flexible printed circuit board 400.

According to an embodiment, as two conductive layers are formed on both sides with respect to the insulating layer 450, power loss may be reduced compared to an embodiment in which one conductive layer is disposed within the flexible printed circuit board 400.

According to an embodiment, each conductive layer configured by one power line 420, one signal line 430, and one bonding member 440 may be electrically separated through the insulating layer 450.

According to an embodiment, in a multilayer structure as described above, the power line 420, the signal line 430, and the bonding member 440 disposed on each layer can be configured to accommodate circuits of mutually different functions. Such an interlayer separation structure may be effective for high-speed signal transmission or the like, and each layer may be designed to have different line widths, inter-line distances, and material characteristics depending on the usage.

FIG. 11 is a schematic illustration of the shape of the flexible printed circuit board 400 according to an embodiment of the disclosure before cutting. In this illustration, for ease of description of the configuration, an approximate shape in a state before cutting during a manufacturing process is shown, and the flexible printed circuit board 400 is not limited to the shape shown in this example. For example, the same may be modified into various shapes depending on the application position, circuit design, or component arrangement structure. According to an embodiment, although the ground portion 410 is described in an example configuration as having substantially the same shape as the shape when the flexible printed circuit board 400 is viewed from the first direction, the disclosure is not limited thereto. For example, the ground portion 410 may be configured in a planar shape wider than the flexible printed circuit board 400 and then formed into substantially the same shape as the shape when the flexible printed circuit board 400 is viewed from the first direction through cutting.

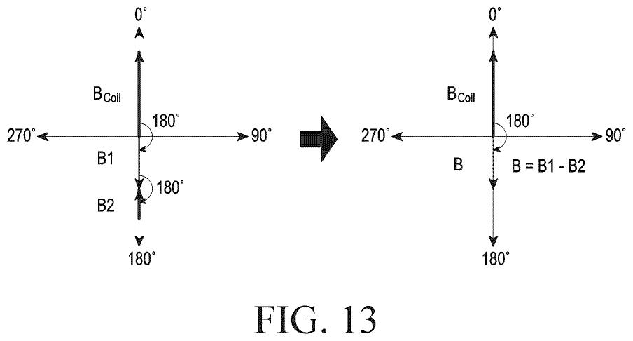

FIG. 12 is a diagram illustrating a ground portion according to various embodiments. FIG. 13 is a diagram illustrating a magnetic field in a ground portion according to various embodiments. FIG. 14 is a diagram illustrating a portion of a flexible printed circuit board according to various embodiments.

The embodiments of FIG. 12 to FIG. 14 may be combined with the embodiments of FIG. 1 to FIG. 11 or FIG. 15 to FIG. 20.

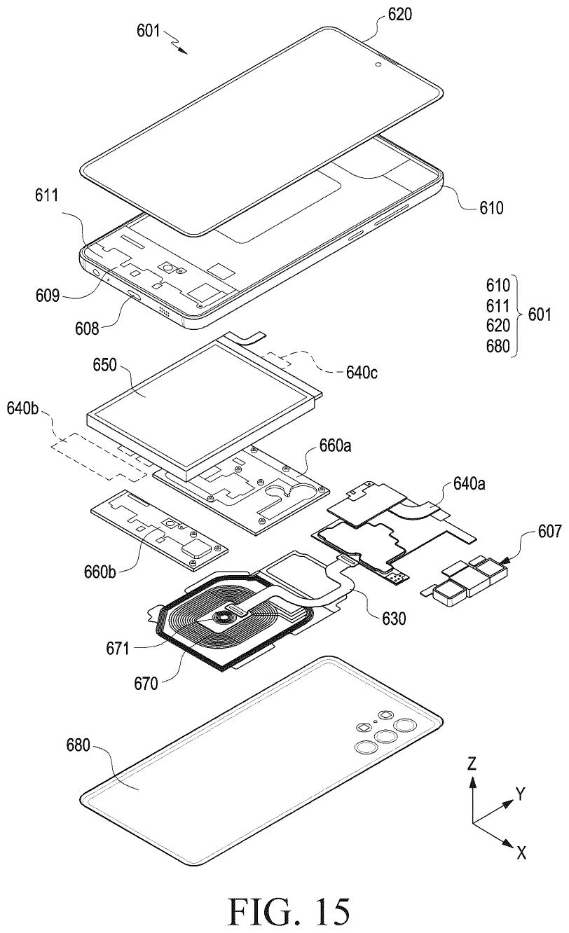

Components described with reference to FIG. 12 to FIG. 14 may be partially or entirely the same as components described with reference to FIG. 1 to FIG. 11. Components described with reference to FIG. 12 to FIG. 14 may be partially or entirely the same as components described with reference to FIG. 15 to FIG. 20.

In the case of a comparative example formed of a single ground layer such as the second ground portion G′ according to FIG. 12, an eddy current I′ may be formed in the second ground portion G′, and a magnetic field B′ may be induced in the second ground portion G′.

The amount of power loss P′ due to the second ground portion 410′ may be a value obtained by multiplying the resistance R of the above-described wireless charging coil (e.g., the wireless charging coil 500 of FIG. 4) by the square of the eddy current I′ according to the following equation:

P′=I′²*R [Equation 1]

According to an embodiment, the ground portion 410 may include a second ground layer G2, a second ground layer G1, and an insulating layer 412 disposed between the first ground layer G1 and the first ground layer G2.

According to an embodiment, the second ground layer G2 may be electrically spaced apart from the first ground layer G1 via the insulating layer A and may be stacked in the first direction (e.g., the −Z-axis direction) such that a counter magnetic field B2 is induced in the first ground layer G1 in a direction opposite to the magnetic field formed in the second ground layer G2.

According to one embodiment, when an external magnetic field generated by an AC current affects the ground G, a first current I1 having a clockwise direction based on the orientation of the first ground layer G1 may be induced in the first ground layer G1. Such a current may correspond to an eddy current generated in the first ground layer G1. Accordingly, a first magnetic field B11 may be induced in the first ground layer G1.

According to one embodiment, since the second ground layer G2 is electrically spaced apart from the first ground layer G1, a second magnetic field B2 functioning as a counter magnetic field corresponding to the first magnetic field B11 may be induced in the second ground layer G2. In addition, a second current I2 may be induced in the second ground layer G2 by a magnetic field B12 influencing the second ground layer G2.

According to an embodiment, according to Equation 2 below, the amount of power loss may be reduced in proportion to the square of the second current I2, which is the amount of current that may be induced in the second ground layer G2 by the second magnetic field B2, and as a result, power efficiency may be improved.

P=I₁²*R−I₂²*R [Equation 2]

Referring to FIG. 13, in case that a magnetic field of intensity B_{coil} is induced from a wireless charging coil (e.g., the wireless charging coil 500 of FIG. 4), a first magnetic field B1 may be induced in the ground portion G, and a second magnetic field B2 having a phase difference of 180 degrees from the first magnetic field B1 may be induced in the second ground layer G2. Accordingly, the intensity of the total magnetic field B formed in the ground portion G may be reduced, thereby reducing the eddy current, and this may reduce power loss caused by the eddy current.

Referring to FIG. 14, a ground portion according to a comparative embodiment may include a first ground portion 410a′ and a second ground portion 410b′. The ground portion according to the comparative embodiment may be configured as a single ground.

Referring to FIG. 14, in an embodiment, the ground portion 410 may include a first ground portion 410a and a second ground portion 410b, and the first ground portion 410a and the second ground portion 410b may be disposed on the upper side (e.g., the first direction, the −Z-axis direction) and the lower side (e.g., the second direction, the +Z-axis direction) of the flexible printed circuit board 400.

According to an embodiment, the first ground portion 410a includes a (1-1)^{th} ground layer 411a, a (1-2)^{th} ground layer 413a, and a first insulating layer 412a disposed between the (1-1)^{th} ground layer 411a and the (1-2)^{th} ground layer 413a, thereby reducing wireless charging power loss due to the eddy current generated by the magnetic field.

According to an embodiment, the second ground portion 410b includes a (2-1)^{th} ground layer 411b, a (2-2)^{th} ground layer 413b, and a second insulating layer 412b disposed between the (2-1)^{th} ground layer 411b and the (2-2)^{th} ground layer 413b, thereby reducing wireless charging power loss due to the eddy current generated by the magnetic field.

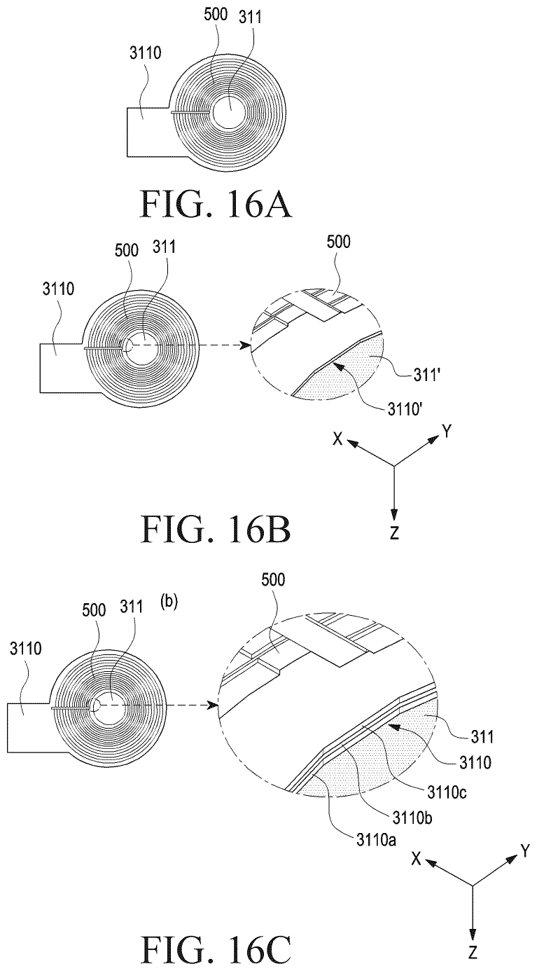

In an embodiment, although the insulating layer 412 is illustrated as an empty space by way of example, the disclosure is not limited thereto, and the insulating layer 412 may be a layer formed of an insulating material (e.g., polyimide) like the antenna insulating layer 3110b of FIG. 16.

In an embodiment, although the (1-1)^{th} ground layer 411a, the (1-2)^{th} ground layer 413a, the (2-1)^{th} ground layer 411b, and the (2-2)^{th} ground layer 413b are described as being completely electrically spaced apart by way of example, the disclosure is not limited thereto, and eddy current loss may be reduced, even if the (1-1)^{th} ground layer 411a, the (1-2)^{th} ground layer 413a, the (2-1)^{th} ground layer 411b, and the (2-2)^{th} ground layer 413b are partially bonded, at locations where no eddy current is generated by magnetic fields.

FIG. 15 is an exploded perspective view of an example electronic device according to various embodiments.

The embodiment of FIG. 15 may be combined with the embodiments of FIG. 1 to FIG. 14 or FIG. 16A to FIG. 20.

Components described with reference to FIG. 15 may be partially or entirely the same as components described with reference to FIG. 1 to FIG. 14. Components described with reference to FIG. 15 may be partially or entirely the same as components described with reference to FIG. 16A to FIG. 20.

According to an embodiment, the ground portion 2110; 3110; 410 may be applicable to various types of electronic devices.

Referring to FIG. 15, the electronic device 601 (e.g., a bar-type electronic device) may include a side structure 610, a first support member 611 (e.g., a bracket), a front plate 620, at least one printed circuit board (or substrate assembly) 640a, 640b, a battery 650, a second support member 660a, 660b (e.g., a rear case), an antenna module 671, a camera assembly 607, and/or a rear plate 680.

According to an embodiment, the electronic device 601 may include a port insertion opening 608. The port insertion opening 608 may be formed in a portion of the housing 601. The port insertion opening 608 may communicate with an external space of the housing 601. The electronic device 601 may be connected to an external device (e.g., a USB port, a charging cable), and the external device may be inserted into the port insertion opening 608.

According to an embodiment, the electronic device 601 may include an antenna 609.

According to an embodiment, the antenna module 671 may be disposed on one surface formed along the first direction (e.g., the −X-axis direction) of the coil assembly 670, and the antenna module 671 may be located between the coil assembly 670 and the rear plate 607 of the electronic device.

According to an embodiment, the antenna module 671 may be protected from external impacts or interference through the rear plate 607.

According to an embodiment, when including multiple printed circuit boards 640a, 640b, the electronic device 101 may include at least one flexible printed circuit board 640c to electrically connect different printed circuit boards. For example, the printed circuit boards 640a, 640b may include a first circuit board 640a disposed above the battery 650 (e.g., in the +Y-axis direction) and a second circuit board 640b disposed below the battery 650 (e.g., in the −Y-axis direction), and the flexible printed circuit board 640c may electrically connect the first circuit board 640a and the second circuit board 640b.

According to an embodiment, the first circuit board 640a may be electrically connected to the wireless charging coil of the coil assembly 670 and/or the antenna module 671 by the flexible printed circuit board 630.

Although a watch-type wearable electronic device and a bar-type electronic device are described in the disclosure as examples of the electronic device, the technical idea of the disclosure is not limited thereto. For example, the electronic device may be equally applied to various types of electronic devices such as a plate-type electronic device, foldable electronic device, or an electronic device including a hinge structure such as a laptop PC. The structure according to an embodiment may be applied to various electronic devices in that the same may implement structures for efficient wireless power transmission and electromagnetic shielding even within a limited space.

FIGS. 16A, 16B and 16C are diagrams illustrating a portion of a sensor module according to various embodiments.

The embodiment of FIGS. 16A, 16B, and 16C may be combined with the embodiments of FIG. 1 to FIG. 15 or FIG. 17 to FIG. 20.

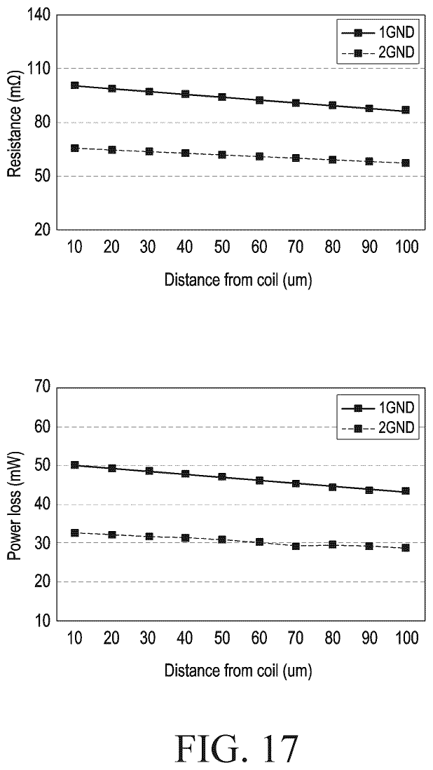

Components described with reference to FIGS. 16A, 16B, and 16C may be partially or entirely the same as components described with reference to FIG. 1 to FIG. 15. Components described with reference to FIGS. 16A, 16B, and 16C may be partially or entirely the same as components described with reference to FIG. 17 to FIG. 20.

The description of the antenna module 311 according to this illustration may be applied substantially identically to the description of the antenna 3111 according to FIG. 5A. According to an embodiment, the antenna module 311 according to this illustration may be formed as various types of antennas such as a microstrip antenna, a high-frequency band antenna, a patch antenna, or a modified structure thereof.

Further, the shape of the antenna module 311 is not limited to a specific shape, and may be formed in various shapes such as rectangular, curved, or ring-shaped, for example. Such modifications may be designed in consideration of characteristics of the space in which the antenna module 311 is disposed, frequency characteristics, radiation direction, or the like.

Referring to FIGS. 16A, 16B and 16C, the antenna module 311 may include a ground portion 3110. According to an embodiment, the ground portion 3110 may include a first ground layer 3110a and a second ground layer 3110c formed spaced apart in the first direction (e.g., the −Z-axis direction), and an insulating layer 3110b disposed between the first ground layer 3110a and the second ground layer 3110c.

According to an embodiment, as the ground portion 3110 is formed as a two-layer ground spaced apart in the first direction (e.g., the −Z-axis direction), power loss due to an eddy current caused by a magnetic field generated during wireless charging may be reduced.

As a comparative example, in the case of an antenna module 311′ formed of only a single ground layer, a magnetic field induced from the wireless charging coil 500 may be concentrated on the single ground layer 3110′, thereby forming a strong eddy current, which may increase power loss.

According to an embodiment, as the first ground layer 3110a and the second ground layer 3110c are stacked with the insulating layer 3110b interposed therebetween, a counter magnetic field may be induced in the second ground layer 3110c in a direction opposite to the magnetic field formed by the first ground layer 3110a. This may reduce power loss due to eddy currents as described above.

According to an embodiment, the counter magnetic field induced in the second ground layer 3110c may counterbalance the magnetic field formed in the ground portion 3110, thereby suppressing eddy current generation in the antenna module 311 and reducing power loss resulting therefrom.

Although the insulating layer 3110b is illustrated in this illustration as a separate layer made of an insulating material (e.g., polyimide) by way of example, the disclosure is not limited thereto, and the insulating layer 3110b may be an empty space as long as the same can electrically separate the insulating layer 412 of FIG. 14 and the first ground layer 3110a and the second ground layer 3110c.

Although the first ground layer 3110a and the second ground layer 3110c are described in this illustration as being completely electrically spaced apart by way of example, the disclosure is not limited thereto, eddy current may can be reduced, even if the first ground layer 3110a and the second ground layer 3110c are partially bonded, at locations where eddy current generation due to a magnetic field does not occur.

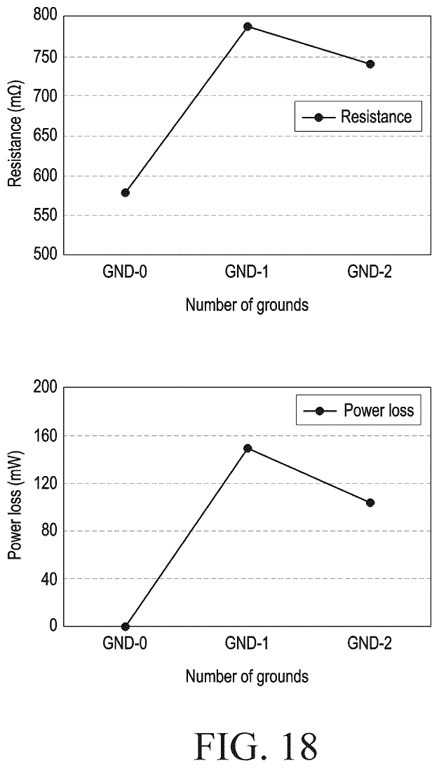

FIG. 17 includes graphs illustrating the effect of a ground portion according to various embodiments. FIG. 18 includes graphs illustrating the effect of a ground portion according to various embodiments.

The embodiments of FIG. 17 and FIG. 18 may be combined with the embodiments of FIG. 1 to FIG. 16C or FIG. 19 to FIG. 20.

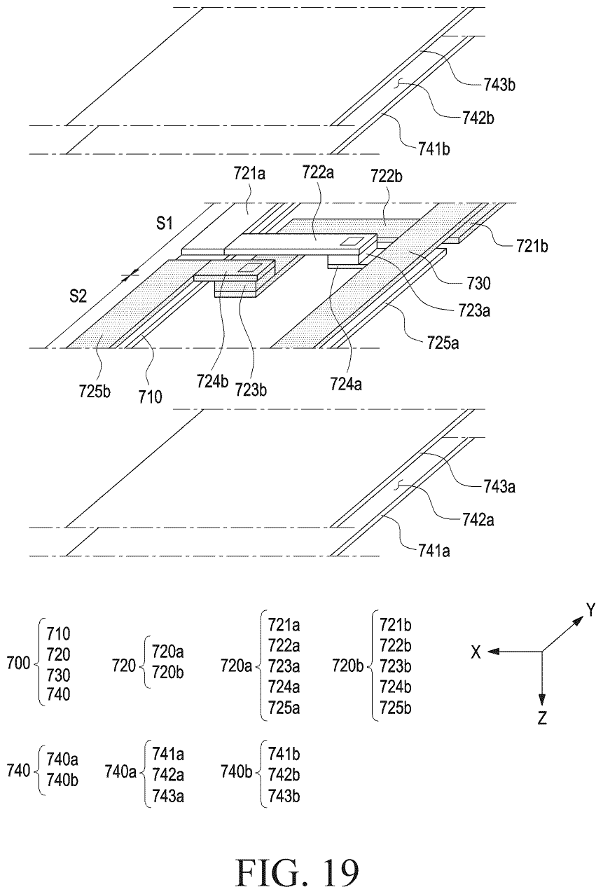

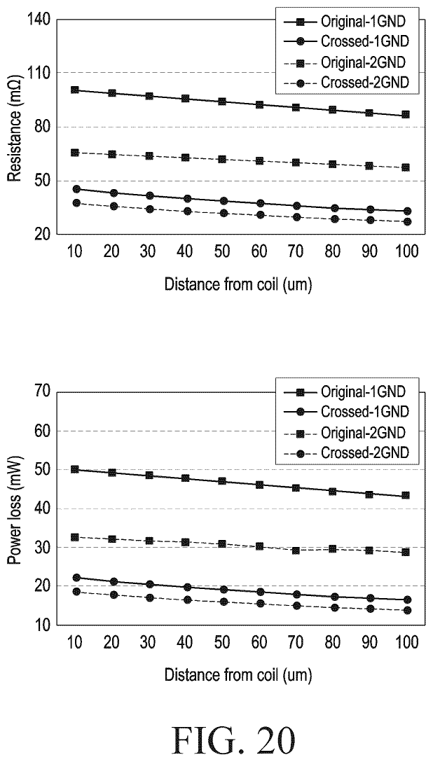

Components described with reference to FIG. 17 and FIG. 18 may be partially or entirely the same as components described with reference to FIG. 1 to FIG. 16C. Components described with reference to FIG. 17 and FIG. 18 may be partially or entirely the same as components described with reference to FIG. 19 to FIG. 20.

Referring to FIG. 17 and FIG. 18, in case that two ground layers electrically spaced apart in the first direction (e.g., the −X-axis direction) (e.g., the above-described ground layers 411, 413 of FIG. 14) are applied, it may be confirmed that resistance and power loss are significantly reduced compared to the case where a single ground layer is applied.

According to an embodiment, providing two ground layers electrically spaced apart in the first direction (e.g., the −X-axis direction) (e.g., the above-described ground layers 411, 413 of FIG. 14) within the flexible printed circuit board 400 may be advantageous in that electrical loss is remarkably reduced compared to a structure including a single ground layer.

For example, the result of measuring the amount of power loss under the condition that a current of 1 A is applied to the wireless charging coil (the above-described wireless charging coil 500 of FIG. 4) confirms that, in the structure including two ground layers electrically spaced apart in the first direction (e.g., the −X-axis direction) (e.g., the above-described ground layers 411, 413 of FIG. 14) according to an embodiment, resistance and power loss are reduced by approximately 35% compared to the structure including a single ground layer.

According to an embodiment, it may be interpreted that two ground layers electrically spaced apart in the first direction (e.g., the −X-axis direction) (e.g., the above-described ground layers 411, 413 of FIG. 14) effectively disperse the eddy current generated by the magnetic field and compensate for induced loss through the counter magnetic field formed between them, thereby reducing power loss.

As such, the structure including two ground layers electrically spaced apart in the first direction (e.g., the −X-axis direction) (e.g., the above-described ground layers 411, 413 of FIG. 14) according to an embodiment may be useful not only for improving wireless charging efficiency but also for enhancing electrical performance in highly integrated electronic devices requiring low power consumption.

FIG. 17 confirms that, regardless of the distance between the wireless charging coil (e.g., the wireless charging coil 500 of FIG. 4) and the ground layer (e.g., the above-described ground layers 411, 413 of FIG. 14), the resistance and power loss are reduced by approximately 35% in the structure including two ground layers electrically spaced apart in the first direction (e.g., the −X-axis direction) (e.g., the above-described ground layers 411, 413 of FIG. 14), compared to the structure including a single ground layer.

Referring to FIG. 18, application of an antenna module (e.g., the above-described antenna module 311 of FIG. 16) including two ground layers electrically spaced apart in the first direction (e.g., the −X-axis direction) (e.g., the above-described first ground layer 3110a and second ground layer 3110c of FIG. 16) according to an embodiment is advantageous in that the electrical loss is significantly reduced by approximately 35% compared to the case including a single ground layer.

For example, in case that the antenna module (e.g., the above-described antenna module 311 of FIG. 16) includes two ground layers electrically spaced apart in the first direction (e.g., the −X-axis direction) (e.g., the above-described first ground layer 3110a and second ground layer 3110c of FIG. 16) according to an embodiment, the resistance and power loss are accordingly reduced by approximately 35% compared to the structure including a single ground layer. As a result, the two electrically spaced ground layers may reduce overall power loss, thereby providing a structure advantageous for improving signal quality in a high-frequency environment and improving power transmission efficiency.

In case that the antenna module (e.g., the above-described antenna module 311 of FIG. 16) includes two ground layers electrically spaced apart in the first direction (e.g., the −X-axis direction) (e.g., the above-described first ground layer 3110a and second ground layer 3110c of FIG. 16) according to an embodiment, the same may have higher power loss and resistance values than the case where the ground portion 3110 is excluded.

Although the ground portion 3110 may cause relatively high resistance and power loss, the same may function as an essential component for preventing/reducing malfunction of adjacent electronic components.

FIG. 19 is exploded perspective view illustrating a portion of a flexible printed circuit board according to various embodiments. FIG. 20 includes graphs illustrating the effect of a ground portion according to various embodiments.

The embodiments of FIG. 19 and FIG. 20 may be combined with the embodiments of FIG. 1 to FIG. 18.

Components described with reference to FIG. 19 and FIG. 20 may be partially or entirely the same as components described with reference to FIG. 1 to FIG. 18.

According to an embodiment, the flexible printed circuit board 700 may include a crossing section S1 and an extension section S2 extending from the crossing section S1. In the extension section S2, the first transmission line 710 and the first return line 730 may extend substantially parallel to each other. In the extension section S2, the second transmission line 720 and the second return line 740 may extend substantially parallel to each other. A length of the extension section S2 of the flexible printed circuit board 700 may be greater than a length of the crossing section S1.

According to an embodiment, the flexible printed circuit board 700 may include a first transmission line 720a and a second transmission line 720b connected to one end of a wireless charging coil (e.g., the above-described wireless charging coil 500 of FIG. 5) to transmit AC power to an electronic component.

As an example, the first transmission line 720a may include a first segment 721a extending from a first end portion. The first segment 721a may extend parallel to a first return line 710. As one example, the first segment 721a may extend along the Y-axis direction.

The first transmission line 720a may further include a second segment 722a extending from the first segment 721a toward a second return line 730. The second segment 722a is located on a first conductive layer of the flexible printed circuit board 700 and may extend along the X-axis direction.

According to an embodiment, the first transmission line 720a may further include a third segment 723a extending from the second segment 722a along the Z-axis direction. The third segment 723a may function as a transmission via and may extend to a fourth segment 724a.

The fourth segment 724a may be disposed so as to overlap with the second return line 730 and may be connected to a fifth segment 725a extending substantially parallel to the second return line 730. The fifth segment 725a may be at least partially located in an extension section S2 of the flexible printed circuit board 700.

The second transmission line 720b may include a first segment 721b, a second segment 722b extending toward the second return line 730, a third segment 723b extending along the Z-axis direction, and subsequent fourth segment 724b and fifth segment 725b, each of which may also overlap with the second return line 730 and extend substantially parallel thereto.

As a result, the first transmission line 720a and the second transmission line 720b according to this embodiment may each form a crossed structure with the first return line 710 and the second return line 730, and such a structure may reduce eddy current loss and reduce electromagnetic interference (EMI).

According to an embodiment, a ground portion 740 may be further included in the first direction (e.g., the −Z-axis direction) and/or the second direction (e.g., the +Z-axis direction) of the flexible printed circuit board 700 including a crossed structure.

According to an embodiment, the ground portion 740 may include a first ground portion 740a configured to form the upper structure of the flexible printed circuit board 700, and a second ground portion 740b disposed in the second direction (e.g., the +Z-axis direction) of the flexible printed circuit board 700 and configured to form the lower structure of the flexible printed circuit board 700.

According to an embodiment, the first ground portion 740a and the second ground portion 740b may include two ground layers electrically spaced apart in the first direction (e.g., the −Z-axis direction).

According to an embodiment, the first ground portion 740a and the second ground portion 740b may further include, as described above, first ground layers 741a, 741b, second ground layers 743a, 743b, and insulating layers 742a, 742b disposed between the first ground layers 741a, 741b and the second ground layers 743a, 743b.

According to an embodiment, the first ground portion 740a may include a (1-1)^{th} ground layer 741a, a (1-2)^{th} ground layer 743a, and a first insulating layer 742a disposed between the (1-1)^{th} ground layer 741a and the (1-2)^{th} ground layer 743a, thereby effectively reducing wireless charging power loss due to the eddy current generated by the magnetic field.

According to an embodiment, the second ground portion 740b may include a (2-1)^{th} ground layer 741b, a (2-2)^{th} ground layer 743b, and a second insulating layer 742b disposed between the (2-1)^{th} ground layer 741b and the (2-2)^{th} ground layer 743b, thereby effectively reducing wireless charging power loss due to the eddy current generated by the magnetic field.

It is confirmed, with reference to FIG. 20, that formation of electrically spaced two ground layers in the flexible printed circuit board 700 including a crossed structure reduces the resistance and power loss compared to a structure including a single ground layer.

According to an embodiment, it is confirmed that additional formation of electrically spaced two ground layers in the flexible printed circuit board 700 including a crossed structure reduces the resistance and power loss compared to the flexible printed circuit board 700 including a crossed structure configured by a single ground layer.

As a result, the two ground layers electrically spaced apart in the first direction (e.g., the first ground layers 741a, 741b and the second ground layers 743a, 743b) applied to the flexible printed circuit board 700 according to an embodiment may effectively reduce eddy current loss in the ground layers even when used in combination with other magnetic field cancellation techniques such as a crossed connection structure, and may serve as a technical means practically applicable to various electronic devices requiring high-efficiency wireless charging.

The disclosure relates to an electronic device. According to an example embodiment, an electronic device may include: a housing 210 including a plate 207 configured to form an external appearance of the electronic device in a first direction; a first PCB disposed within the housing 210 and a first electronic component disposed on the first PCB; a second PCB 211 disposed within the housing, disposed on a substantially identical plane with a wireless charging coil 500, and at least partially surrounded by the wireless charging coil 500, and a second electronic component disposed on the second PCB and formed spaced apart from the first PCB in the first direction; a wireless charging coil 500 disposed adjacent to the plate 207 in a second direction opposite to the first direction and configured to transmit and/or receive power with respect to an external electronic device or a wireless power transmission device; a flexible printed circuit board 400 configured to transmit and/or receive power and/or signals between the first electronic component and the second electronic component by connecting the first PCB and the second PCB 211, and disposed so as to at least partially overlap with the wireless charging coil; and a ground portion 410 disposed on a first side of the flexible printed circuit board 400 facing the first direction and/or a second side facing the second direction, wherein the ground portion includes two ground layers configured to be electrically separated from each other by being spaced apart in the second direction and to form magnetic fields in opposite directions.

According to an example embodiment, in connection with the electronic device, when the flexible printed circuit board 400 is viewed from the first direction, a first end portion of the flexible printed circuit board connected to the first PCB may be disposed on an outer side of the wireless charging coil 500, a second end portion of the flexible printed circuit board connected to the second PCB may be disposed on an inner side of the wireless charging coil 500, and a connection portion connecting the first end portion and the second end portion of the flexible printed circuit board 400 may be formed across the wireless charging coil 500.

According to an example embodiment, the electronic device may further include a ground portion 2110; 3110 disposed adjacent to the second electronic component 2111; 311 in the second direction, and the ground portion 2110; 3110 may include two ground layers configured to be electrically separated from each other by being spaced apart in the second direction and to form magnetic fields in opposite directions.

According to an example embodiment, in connection with the electronic device, the ground portion 410 may include a second ground layer G2, an insulating layer 412, and a first ground layer G1 sequentially stacked in the first direction.

According to an example embodiment, in connection with the electronic device, the ground portion 410 may include a first ground portion 410a disposed in the first direction of the flexible printed circuit board 400 and a second ground portion 410b disposed in the second direction of the flexible printed circuit board 400.

According to an example embodiment, in connection with the electronic device, the plurality of conductive lines may include a power line 420 configured to transmit and/or receive power by connecting the first electronic component and the second electronic component, a signal line 430 configured to transmit and/or receive signals by connecting the first electronic component and the second electronic component and a ground line electrically connected to the first ground plane and the second ground plane.

According to an example embodiment, in connection with the electronic device, the signal line 430 may be disposed between the ground portion 410 and the power line 420.

According to an example embodiment, in connection with the electronic device, the power line 420 may be disposed between the ground portion 410 and the signal line 430.

According to an example embodiment, in connection with the electronic device, the flexible printed circuit board 400 may include multiple conductive layers and multiple insulating layers 450 alternately stacked in the first direction, and the multiple conductive layers may include the power line 420 and the signal line 430.

According to an example embodiment, in connection with the electronic device, the first ground portion 410a may include a (1-1)^{th} ground layer 411a, a first insulating layer 412a, and a (1-12^{th} ground layer 413a sequentially stacked in the first direction.

According to an example embodiment, in connection with the electronic device, the second ground portion 410b may include a (2-1)^{th} ground layer 411b, a second insulating layer 412b, and a (2-2)^{th} ground layer 413b sequentially stacked in a second direction opposite to the first direction.

According to an example embodiment, in connection with the electronic device, the multiple conductive layers may further include a bonding member 440, and the bonding member 440 may be configured to bond the power line 420 and the signal line 430.

According to an example embodiment, in connection with the electronic device, the signal line 430 may include a first signal line 430a and a second signal line 430b disposed in parallel in a third direction perpendicular to the first direction.

According to an example embodiment, in connection with the electronic device, the flexible printed circuit board may include a first transmission line 720a and a second transmission line 720b connected to one end of the wireless charging coil 500 and configured to transmit AC power from the wireless charging coil 500 to the electronic component, and a first return line 610 and a second return line 630 connected to the other end of the wireless charging coil 500 and configured to form a return current path of the first transmission line 720a and the second transmission line 720b.

According to an example embodiment, in connection with the electronic device, when the flexible printed circuit board 400 is viewed from above, at least a portion of the first transmission line 720a and at least a portion of the first return line 710 may overlap and extend substantially parallel to each other, and at least a portion of the second transmission line 720b and at least a portion of the second return line 730 may overlap and extend substantially parallel to each other.

According to an example embodiment, in connection with the electronic device, the second electronic component may further include a sensing member 2111 configured to sense external information, a connection portion 2113 connected to the second PCB, and a sensor module power line 2112 configured to transmit and/or receive power between the sensing member 2111 and the connection portion 2113.

According to an example embodiment, in connection with the electronic device, the ground portion 2110 may be disposed in the second direction of the sensing member 2111.

According to an example embodiment, in connection with the electronic device, the ground portion 410 may have a shape substantially identical to the shape when the flexible printed circuit board 400 is viewed from the first direction.

According to an example embodiment, the electronic device may further include a shielding sheet disposed on the plate 207 and the wireless charging coil 500 and configured to overlap with the wireless charging coil 500 when viewed from the first direction.

The disclosure relates to an electronic device. An electronic device may include: a housing 210, 601 including a plate 207, 680 configured to form an external appearance of the electronic device in a first direction; a first PCB disposed within the housing 210; a wireless charging coil 500, 670 disposed adjacent to the plate 207 in a second direction opposite to the first direction and configured to transmit and/or receive power with respect to an external electronic device or a wireless power transmission device; a printed circuit board 400, 311 disposed within the housing and disposed on a substantially identical plane with the wireless charging coil so as to be at least partially surrounded by the wireless charging coil or disposed such that at least a portion thereof overlaps with at least a portion of the wireless charging coil when viewed in the second direction; a ground portion 410, 3110 disposed on a first side of the printed circuit board 400, 311 facing the first direction and/or a second side facing the second direction, wherein the ground portion includes two ground layers that are electrically separated and continuously disposed.

The disclosure relates to a wearable electronic device. According to an example embodiment, a wearable electronic device may include: a housing 210 including a plate 207 configured to form an external appearance of the electronic device in a first direction; a first PCB disposed within the housing 210 and a first electronic component connected to the first PCB; a second PCB disposed within the housing, disposed on a substantially identical plane with a wireless charging coil 500, and at least partially surrounded by the wireless charging coil 500, and a second electronic component disposed on the second PCB and formed spaced apart from the first PCB in the first direction; a wireless charging coil 500 disposed adjacent to the plate 207 in a second direction opposite to the first direction and configured to transmit and/or receive power from an external electronic device or a wireless power transmission device; a flexible printed circuit board 400 configured to transmit and/or receive power and/or signals between the first electronic component and the second electronic component by connecting the first PCB and the second PCB, and disposed so as to at least partially overlap with the wireless charging coil; and a ground portion 2110; 3110; 410 disposed adjacent to the second electronic component 2111; 311 and the flexible printed circuit board 400, wherein the ground portion includes two ground layers spaced apart in the second direction and configured to be electrically separated from each other.

According to an example embodiment, in connection with the wearable electronic device, the ground portion 2110; 3110 adjacent to the second electronic component 2111; 311 may be disposed in the second direction of the second electronic component 2111; 311, and the ground portion 410 adjacent to the flexible printed circuit board 400 may be disposed in the first direction and/or the second direction of the flexible printed circuit board 400.

According to an example embodiment, in connection with the electronic device, the ground portion 410 may include a first ground portion 410a disposed in the first direction of the flexible printed circuit board 400 and a second ground portion 410b disposed in the second direction of the flexible printed circuit board 400, and the flexible printed circuit board may include a power line 420 configured to transmit and/or receive power by connecting the first PCB and the second PCB, and a signal line 430 configured to transmit and/or receive signals by connecting the first electronic component and the second electronic component.

According to an example embodiment, in connection with the electronic device, the first ground portion 410a may include a (1-1)^{th} ground layer 411a, a first insulating layer 412a, and a (1-2)^{th} ground layer 413a sequentially stacked in the first direction.

According to an example embodiment, in connection with the electronic device, the second ground portion 410b may include a (2-1)^{th} ground layer 411b, a second insulating layer 412b, and a (2-2)^{th} ground layer 413b sequentially stacked in a second direction opposite to the first direction.

According to an example embodiment, in connection with the electronic device, the flexible printed circuit board may include a power line 420 configured to transmit and/or receive power by connecting the first PCB and the second PCB, and a signal line 430 configured to transmit and/or receive signals.

The disclosure relates to an electronic device. According to an example embodiment, an electronic device may include: a housing 210 including a plate 207; a first PCB including a first electronic component and a first ground plane; a wireless charging coil 500 disposed adjacent to the plate 207 and configured to receive power with respect to a wireless power transmission device; a second PCB 211 including a second electronic component and a second ground plane, whereint the second electronic component at least partially surrounded by the wireless charging coil 500 when viewed in a direction perpendicular to the plate 207; a flexible printed circuit board 400 electrically connecting the first PCB and the second PCB 211 and the wireless charging coil;. The flexible printed circuit board 400 may include: a first connector configured to be connected to the first PCB; a second connector configured to be connected to the second PCB; a plurality of conductive lines disposed between the first connector and the second connector; and a first ground portion 410a which includes two ground layers that are spaced apart from each other and which is electrically connected to at least one of the first ground plane and the second ground plane. The second connector is electrically connected to the wireless charging coil and the plurality of conductive lines. Two of the plurality of conductive lines may be used as AC power transmission lines for supplying AC power received through the wireless charging coil 500 to the first PCB, and the two ground layers of the first ground portion may be disposed so as to overlap with the AC power transmission lines when viewed in a direction perpendicular to the plate 207.

According to an example embodiment, in connection with the electronic device, the first ground portion 410a may be configured to reduce eddy current loss caused by an external magnetic field.

According to an example embodiment, in connection with the electronic device, the flexible printed circuit board 400 may further include a second ground portion 410b disposed on a side of the plurality of conductive lines opposite to the first ground portion. The second ground portion may include two ground layers disposed spaced apart from each other. The two ground layers of the second ground portion may be disposed so as to overlap with the AC power transmission lines when viewed in a direction perpendicular to the plate 207.

According to an example embodiment, in connection with the electronic device, the first ground portion 410a and the second ground portion 410b may be configured to reduce eddy current loss caused by an external magnetic field.

According to an example embodiment, the plurality of conductive traces may be included in an electronic device and may include a power line 420 configured to transmit and/or receive power by connecting the first PCB and the second PCB, a signal line 430 configured to transmit and/or receive a signal, and a ground line electrically connected to the first ground plane and the second ground plane.

According to an example embodiment, the electronic device may be configured such that the signal line 430 is disposed between the first ground portion 410a and the power line 420, and between the second ground portion 410b and the power line 420.

According to an example embodiment, the electronic device may be configured such that the first ground portion 410a and the second ground portion 410b have shapes substantially identical to a shape of the flexible printed circuit board 400 when viewed in a first direction.

According to an example embodiment, in the ground portion configuration, two grounds may be stacked and disposed such that eddy currents generated during wireless charging can be dispersed, thereby reducing heat generation that may occur in the electronic device.

According to an example embodiment, in the ground portion configuration, two grounds may be stacked and disposed such that signal interference due to a magnetic field that may be caused by eddy current generation can be reduced, thereby securing communication stability.

According to an example embodiment, the electronic device of the disclosure may improve overall reliability of the electronic device by simultaneously suppressing heat generation and interference problems.

Advantageous effects obtainable from the disclosure are not limited to the advantageous effects mentioned above, and other advantageous effects not mentioned herein will be clearly understood by one skilled in the art to which the disclosure pertains.

While the disclosure has been illustrated and described with reference to various example embodiments, it will be understood that the various example embodiments are intended to be illustrative, not limiting. It will be further understood by those skilled in the art that various modifications, alternatives and/or variations of the various example embodiments may be made without departing from the true technical spirit and full technical scope of the disclosure, including the appended claims and their equivalents. It will also be understood that any of the embodiment(s) described herein may be used in conjunction with any other embodiment(s) described herein.

What is claimed is:

1. An electronic device comprising:
a housing including a plate;
a first printed circuit board (PCB) including a first electronic component and a first ground plane;
a wireless charging coil disposed adjacent to the plate, and configured to receive power from a wireless power transmitting device;
a second PCB including a second electronic component and a second ground plane, wherein the second electronic component is at least partially surrounded by the wireless charging coil when viewed in a direction orthogonal to the plate; and
a flexible printed circuit board electrically connecting the first PCB and the second PCB, wherein the flexible printed circuit board comprises:
a first connector configured to connect to the first PCB,
a second connector configured to connect to the second PCB and the wireless charging coil,
a plurality of conductive lines disposed between the first connector and the second connector, and
a first ground portionincluding two ground layers spaced apart from each other which includes two ground layers that are spaced apart from each other and which is electrically connected to at least one of the first ground plane and the second ground plane,
wherein the second connector is electrically connected to the wireless charging coil and the plurality of conductive lines,
wherein two of the conductive lines are used as alternating current (AC) power transmission lines configured to supply AC power received via the wireless charging coil to the first PCB,
wherein when viewed in a direction orthogonal to the plate, the two ground layers of the first ground portion overlap two of the conductive lines used as AC power transmission lines.

2. The electronic device of claim 1,
wherein the first ground portion is configured to reduce an eddy current loss due to an external magnetic field.

3. The electronic device of claim 1,
wherein the flexible printed circuit board further comprises a second ground portion disposed on a side of the plurality of conductive lines opposite to the first ground portion,
wherein the second ground portion comprises two ground layers spaced apart from each other, and
wherein when viewed in a direction orthogonal to the plate, the two ground layers of the second ground portion overlap the two of the conductive lines used as AC power transmission lines.

4. The electronic device of claim 3,
wherein the first ground portion and the second ground portion are configured to reduce an eddy current loss due to an external magnetic field.

5. The electronic device of claim 1,
wherein when the flexible printed circuit board is viewed from a first direction toward a rear side of the electronic device, a first end of the flexible printed circuit board connected to the first PCB is disposed on an outer side of the wireless charging coil, and a second end of the flexible printed circuit board connected to the second PCB is disposed on an inner side of the wireless charging coil, and
a connecting portion of the flexible printed circuit board that connects the first end and the second end extends across the wireless charging coil.

6. The electronic device of claim 1,
wherein the plurality of conductive lines includes:
a power line configured to transmit and/or receive power by electrically connecting the first PCB and the second PCB; and
a signal line configured to transmit and/or receive a signal
a ground line electrically connected to the first ground plane and the second ground plane.

7. The electronic device of claim 6,
wherein the signal line is disposed between the first ground portion and the power line, and between the second ground portion and the power line.

8. The electronic device of claim 6,
wherein the flexible printed circuit board includes a plurality of conductive layers and a plurality of insulating layers alternately stacked in the first direction, and wherein the plurality of conductive layers include the power line and the signal line.

9. The electronic device of claim 1,
wherein the first ground portion includes a first first ground layer, a first insulating layer, and a second first ground layer sequentially stacked in the first direction.

10. The electronic device of claim 3,
wherein the second ground portion includes a first second ground layer, a second insulating layer, and a second second ground layer sequentially stacked in the second direction opposite to the first direction.

11. The electronic device of claim 1,
wherein the first ground portion and the second ground portion have a shape substantially the same as a shape of the flexible printed circuit board when viewed from the first direction.

12. The electronic device of claim 6,
wherein the signal line includes a first signal line and a second signal line arranged in parallel along a third direction perpendicular to the first direction.

13. The electronic device of claim 1,
wherein the flexible printed circuit board includes:
a first transmission line and a second transmission line connected to one end of the wireless charging coil and configured to deliver AC power from the wireless charging coil to the first electronic component; and
a first return line and a second return line connected to the other end of the wireless charging coil and configured to provide a return current path for the first transmission line and the second transmission line;
wherein when viewed from above the flexible printed circuit board,
at least a portion of the first transmission line and at least a portion of the first return line overlap and extend substantially in parallel, and
at least a portion of the second transmission line and at least a portion of the second return line overlap and extend substantially in parallel.

14. The electronic device of claim 1,
wherein the second electronic component includes:
a sensing member comprising circuitry configured to sense external information;
a connection portion comprising a connector connected to the second PCB; and
a sensor module power line configured to transmit and/or receive power between the sensing member and the connection portion.

15. The electronic device of claim 1, further comprising:
a shielding sheet disposed between the plate and the wireless charging coil, overlapping the wireless charging coil when viewed from the first direction.

16. An electronic device comprising:
a housing including a plate configured to form an external appearance of the electronic device in a first direction;
a first printed circuit board (PCB) disposed within the housing and a first electronic component connected to the first PCB;
a second PCB disposed within the housing, disposed on a substantially same plane with a wireless charging coil, and at least partially surrounded by the wireless charging coil, and a second electronic component disposed on the second PCB, the second electronic component being spaced apart from the first PCB in the first direction;
a wireless charging coil disposed adjacent to the plate in a second direction opposite to the first direction and configured to transmit and/or receive power from an external electronic device and/or a wireless power transmission device;
a flexible printed circuit board configured to transmit and/or receive power and/or signals between the first electronic component and the second electronic component by connecting the first PCB and the second PCB, and disposed to at least partially overlap with the wireless charging coil; and
a ground portion disposed adjacent to the second electronic component and the flexible printed circuit board,
wherein the ground portion comprises two ground layers spaced apart in the second direction and electrically separated from each other.

17. The electronic device of claim 16, wherein the ground portion adjacent to the second electronic component is disposed in the second direction of the second electronic component, and
wherein the ground portion adjacent to the flexible printed circuit board is disposed in the first direction and/or the second direction of the flexible printed circuit board.

18. The electronic device of claim 16, wherein the ground portion comprises a first ground portion disposed in the first direction of the flexible printed circuit board and a second ground portion disposed in the second direction of the flexible printed circuit board, and
wherein the flexible printed circuit board comprises:
a power line configured to transmit and/or receive power by connecting the first PCB and the second PCB; and
a signal line configured to transmit and/or receive signals by connecting the first PCB and the second PCB.

19. The electronic device of claim 18, wherein the first ground portion comprises a first first ground layer, a first insulating layer, and a second first ground layer sequentially stacked in the first direction, and
wherein the second ground portion comprises a first second ground layer, a second insulating layer, and a second second ground layer sequentially stacked in a second direction opposite to the first direction.

20. An electronic device comprising:
a housing comprising a plate configured to form an external appearance of the electronic device in a first direction;
a first printed circuit board (PCB) disposed within the housing;
a wireless charging coil disposed adjacent to the plate in a second direction opposite to the first direction and configured to transmit and/or receive power with respect to an external electronic device and/or a wireless power transmission device;
a printed circuit board disposed within the housing and disposed on a substantially same plane with the wireless charging coil to be at least partially surrounded by the wireless charging coil or disposed such that at least a portion thereof overlaps at least a portion of the wireless charging coil when viewed in the second direction; and
a ground portion disposed on a first side of the printed circuit board facing the first direction and/or a second side facing the second direction,
wherein the ground portion comprises two ground layers electrically separated and continuously disposed.
